(19) United States
(12) Patent Application Publication
(10) Pub. No.: US 2025/0301626 A1
(43) Pub. Date: Sep. 25, 2025

(54) SEMICONDUCTOR MEMORY DEVICE

(71) Applicant: SAMSUNG ELECTRONICS CO., LTD., Suwon-si (KR)

(72) Inventors: Jae Won NA, Suwon-si (KR); Hyeon Tae KIM, Suwon-si (KR); Chan Hee HAN, Suwon-si (KR)

(73) Assignee: SAMSUNG ELECTRONICS CO., LTD., Suwon-si (KR)

(21) Appl. No.: 18/910,868

(22) Filed: Oct. 9, 2024

(30) Foreign Application Priority Data
Mar. 25, 2024 (KR) 10-2024-0040637

(51) Int. Cl. H10B 12/00

(52) U.S. Cl. CPC H10B 12/315; H10B 12/09; H10B 12/50

(57) ABSTRACT

A semiconductor device may include: a bit-line on a substrate and extending in a first direction; a protruding insulating pattern on the bit-line and including a channel trench; a channel structure extending along a portion of a sidewall and a lower surface of the channel trench, wherein the channel structure includes a first channel pattern, and a second channel pattern spaced apart from the first channel pattern in the first direction; a first word-line between the first channel pattern and the second channel pattern and extending in a second direction; a second word-line between the first channel pattern and the second channel pattern, and extending in the second direction; a liner film between the protruding insulating pattern and the first channel pattern, and between the protruding insulating pattern and the second channel pattern; and first and second capacitors between and respectively connected to the first and second channel patterns.

### CROSS-REFERENCE TO RELATED APPLICATION

This application claims priority from Korean Patent Application No. 10-2024-0040637, filed on Mar. 25, 2024, in the Korean Intellectual Property Office, and all the benefits accruing therefrom under 35 U.S.C. 119, the contents of which in its entirety are herein incorporated by reference.

### BACKGROUND

### 1. Technical Field

Embodiments of the present disclosure relate to a semiconductor memory device, and more specifically, to a semiconductor memory device including a vertical channel transistor (VCT).

### 2. Description of Related Art

In order to have high performance and a low price of a semiconductor memory device as demanded by consumers, it is required to increase integration of the semiconductor memory device. The integration of the semiconductor memory device is an important factor in determining a price thereof. Thus, the semiconductor memory device particularly having increased integration is required.

Integration of a two-dimensional (2D) or planar semiconductor memory device is largely determined based on an occupancy area of a unit memory cell, and therefore is greatly affected by a level of a fine pattern formation skill. However, ultra-expensive equipment is required for formation of fine patterns. Thus, although the integration of the 2D semiconductor memory device is increasing, the increase thereof is limited. Accordingly, a semiconductor memory device including a vertical channel transistor in which a channel extends in a vertical direction is being proposed.

### SUMMARY

According to embodiments of the present disclosure, a semiconductor memory device is provided with improved electrical characteristics.

Aspects achieved by embodiments of the present disclosure are not limited to the above-mentioned aspect. Other aspects and advantages according to embodiments of the present disclosure that are not mentioned may be understood based on the following description, and may be more clearly understood based on embodiments of the present disclosure. Further, it will be easily understood that the aspects and advantages according to embodiments of the present disclosure may be realized using means described in the claims and combinations thereof.

According to embodiments of the present disclosure, a semiconductor memory device may be provided and include: a substrate; a bit-line on the substrate and extending in a first direction; a protruding insulating pattern on the bit-line and including a channel trench, wherein the channel trench exposes the bit-line and extends in a second direction intersecting the first direction; a channel structure extending along a portion of a sidewall of the channel trench and a lower surface of the channel trench, wherein the channel structure includes a first channel pattern and a second channel pattern spaced apart from the first channel pattern in the first direction; a first word-line between the first channel pattern and the second channel pattern and extending in the second direction; a second word-line between the first channel pattern and the second channel pattern and extending in the second direction, wherein the second word-line is spaced apart from the first word-line in the first direction; a liner film between the protruding insulating pattern and the first channel pattern, and between the protruding insulating pattern and the second channel pattern, wherein the liner film extends along at least a portion of a sidewall of the protruding insulating pattern, and includes fluorine; and a first capacitor and a second capacitor between the first channel pattern and the second channel pattern, and respectively connected to the first channel pattern and the second channel pattern.

According to embodiments of the present disclosure, a semiconductor memory device may be provided and include: a substrate; a bit-line on the substrate and extending in a first direction; a protruding insulating pattern on the bit-line and including a channel trench, wherein the channel trench exposes the bit-line and extends in a second direction intersecting the first direction; a channel structure extending along a portion of a sidewall of the channel trench and a lower surface of the channel trench, wherein the channel structure includes a first channel pattern including a metal oxide, and a second channel pattern spaced apart from the first channel pattern in the first direction, and wherein the second channel pattern includes the metal oxide; a first word-line between the first channel pattern and the second channel pattern and extending in the second direction; a second word-line between the first channel pattern and the second channel pattern and extending in the second direction, wherein the second word-line is spaced apart from the first word-line in the first direction; a liner film between the protruding insulating pattern and the first channel pattern, and between the protruding insulating pattern and the second channel pattern, wherein the liner film extends along at least a portion of a sidewall of the protruding insulating pattern, and includes fluorine; a first capacitor and a second capacitor between the first channel pattern and the second channel pattern, and respectively connected to the first channel pattern and the second channel pattern; and at least one landing pad connecting the first channel pattern and the first capacitor to each other, and connecting the second channel pattern and the second capacitor to each other.

According to embodiments of the present disclosure, a semiconductor memory device may be provided and include: a substrate; a peripheral gate structure on the substrate; a bit-line on the peripheral gate structure and extending in a first direction; a protruding insulating pattern on the bit-line and including a channel trench, wherein the channel trench exposes the bit-line and extends in a second direction intersecting the first direction; a channel structure extending along a portion of a sidewall of the channel trench and a lower surface of the channel trench, wherein the channel structure includes a first channel pattern including a metal oxide, and a second channel pattern spaced apart from the first channel pattern in the first direction, wherein the second channel pattern includes the metal oxide; a first word-line between the first channel pattern and the second channel pattern and extending in the second direction; a second word-line between the first channel pattern and the second channel pattern, and extending in the second direction, wherein the second word-line is spaced apart from the first word-line in the first direction; a liner film between the protruding insulating pattern and the first channel pattern, and between the protruding insulating pattern and the second channel pattern, wherein the liner film extends along at least a portion of a sidewall of the protruding insulating pattern, and includes fluorine; a first capacitor and a second capacitor between the first channel pattern and the second channel pattern, and respectively connected to the first channel pattern and the second channel pattern; and at least one landing pad connecting the first channel pattern and the first capacitor to each other, and connecting the second channel pattern and the second capacitor to each other, wherein the bit-line includes: a protruding portion overlapping with the protruding insulating pattern in a vertical direction; and a non-protruding portion that does not overlap with the protruding insulating pattern in the vertical direction, wherein the channel structure is on the non-protruding portion, wherein a vertical level of an upper surface of the protruding portion is higher than a vertical level of an upper surface of the non-protruding portion, and wherein the liner film extends from a portion of a sidewall of the protruding portion to the sidewall of the protruding insulating pattern.

### BRIEF DESCRIPTION OF DRAWINGS

The above and other aspects and features of the present disclosure will become more apparent by describing in detail example embodiments thereof with reference to the attached drawings, in which:

FIG. 1 is a layout diagram for illustrating a semiconductor memory device according to some embodiments of the present disclosure.

FIG. 2 is a cross-sectional view cut along lines A-A and B-B in FIG. 1.

FIG. 3 is a cross-sectional view cut along lines C-C and D-D in FIG. 1.

FIG. 4 is an enlarged view of a portion P of FIG. 2.

FIGS. 5 to 9 are diagrams for illustrating a semiconductor memory device according to some embodiments of the present disclosure.

FIG. 10 is a diagram for illustrating a semiconductor memory device according to some embodiments of the present disclosure.

FIG. 11 is a diagram for illustrating a semiconductor memory device according to some embodiments of the present disclosure.

FIG. 12 and FIG. 13 are diagrams for illustrating a semiconductor memory device according to some embodiments of the present disclosure.

FIGS. 14 to 17 are diagrams for illustrating a semiconductor memory device according to some embodiments of the present disclosure.

FIGS. 18 to 34 are diagrams for illustrating a semiconductor memory device according to some embodiments of the present disclosure.

FIG. 35 and FIG. 36 are diagrams of intermediate structures corresponding to intermediate steps of a semiconductor memory device manufacturing method according to some embodiments of the present disclosure.

### DETAILED DESCRIPTION

Although terms such as “first,” “second,” “upper,” and “lower” are used herein to describe various elements or components, these element or components are not limited by the terms. Rather, the terms are merely used herein to distinguish one element or component from another element or component. Therefore, a first element or component as mentioned below may also be a second element or component within the technical spirit of the present disclosure. Further, a lower element or component as mentioned below may also be an upper element or component within the technical spirit of the present disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, non-limiting example embodiments of the present disclosure will be described in detail with reference to the accompanying drawings. The same reference numerals are used for the same components in the drawings, and duplicate descriptions thereof may be omitted.

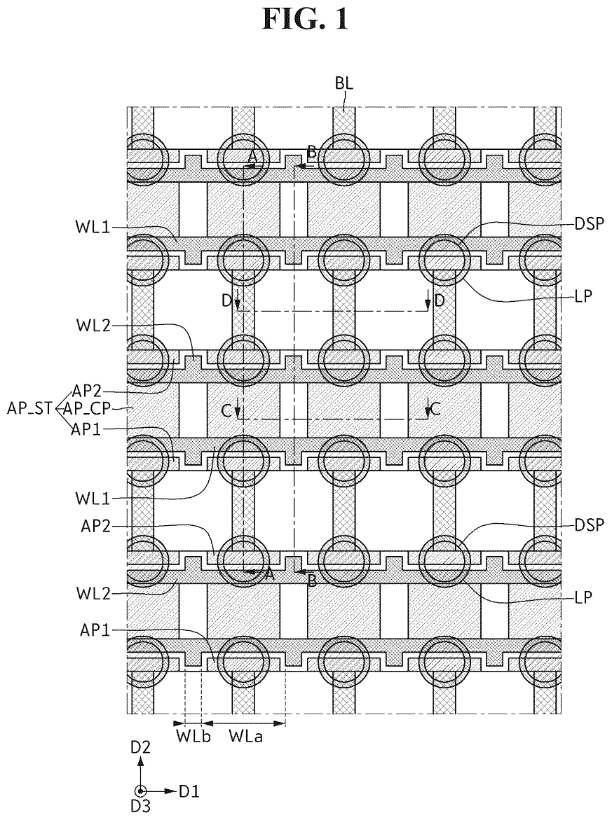

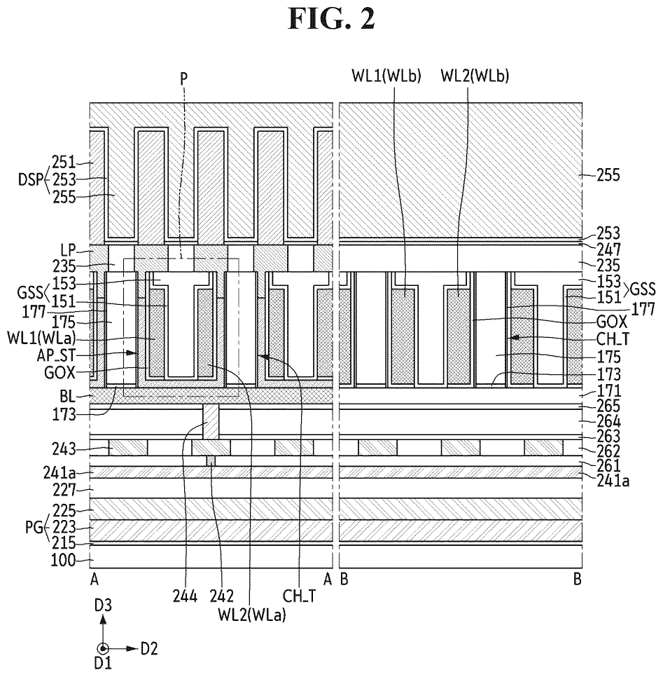

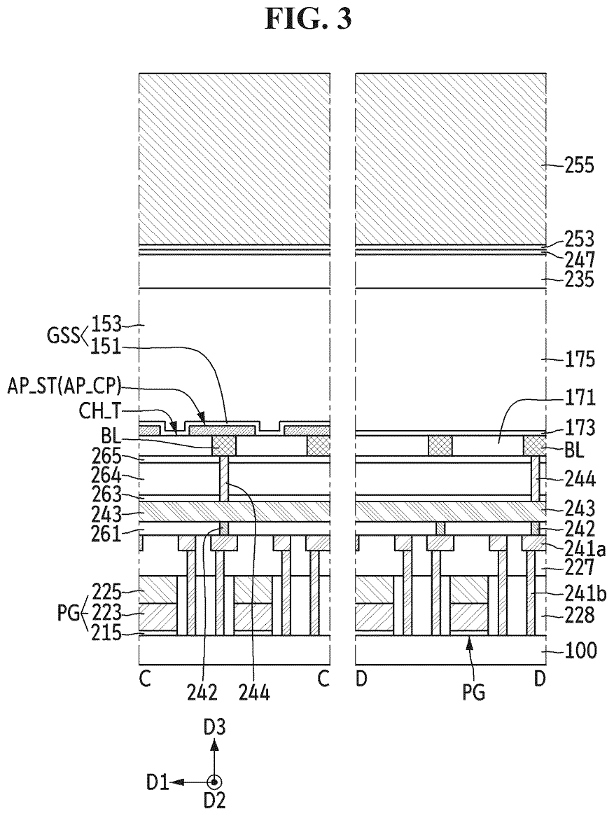

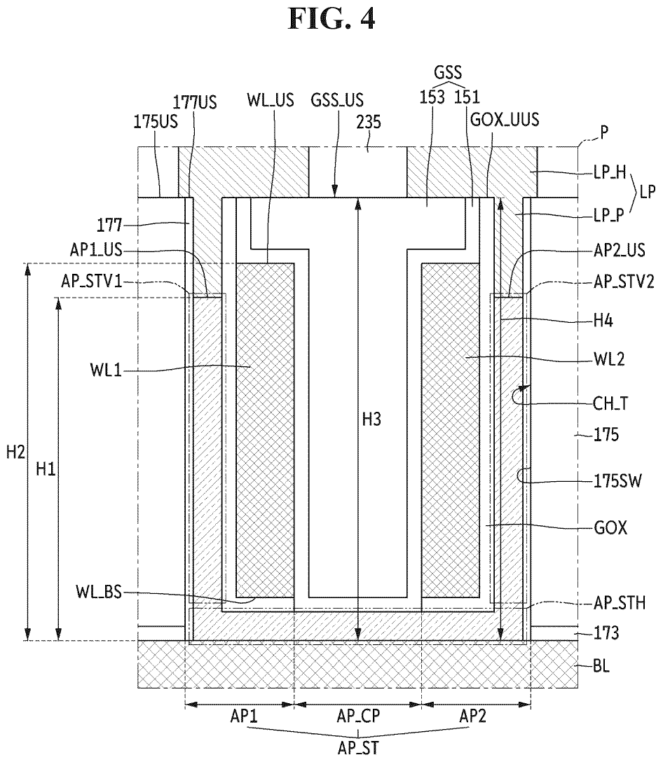

FIG. 1 is a layout diagram for illustrating a semiconductor memory device according to some embodiments of the present disclosure. FIG. 2 is a cross-sectional view cut along lines A-A and B-B in FIG. 1. FIG. 3 is a cross-sectional view cut along lines C-C and D-D in FIG. 1. FIG. 4 is an enlarged view of a P portion of FIG. 2.

Hereinafter, a semiconductor memory device according to some embodiments of the present disclosure is described with reference to FIGS. 1 to 4.

A semiconductor memory device according to some embodiments of the present disclosure may include memory cells, each including a vertical channel transistor (VCT).

Referring to FIGS. 1 to 4, the semiconductor memory device according to some embodiments of the present disclosure may include a substrate 100, a peripheral gate structure PG, bit-lines BL, word-lines (e.g., a first word line WL1 and a second word line WL2), channel structures AP_ST, a protruding insulating pattern 175, a liner film 177, a landing pad LP, and a data storage pattern DSP.

The substrate 100 may be a silicon substrate, or may include a material other than silicon, such as silicon germanium, indium antimonide, lead telluride compound, indium arsenide, indium phosphide, gallium arsenide, or gallium antimonide. However, embodiments of the present disclosure are not limited thereto.

The peripheral gate structure PG may be disposed on the substrate 100. The substrate 100 may include a cell array area and a peripheral circuit area. The peripheral gate structure PG may be disposed across and on the cell array area and the peripheral circuit area. In other words, a portion of the peripheral gate structure PG may be disposed on the cell array area of the substrate 100, and the remainder of the peripheral gate structure PG may be disposed on the peripheral circuit area of the substrate 100.

The peripheral gate structure PG may be included in a sensing transistor, a transfer transistor, and a driving transistor. A type of a transistor disposed in each of the cell array area and the peripheral circuit area may vary depending on a design layout of the semiconductor memory device.

The peripheral gate structure PG may include a peripheral gate insulating film 215, a peripheral lower conductive pattern 223, and a peripheral upper conductive pattern 225.

The peripheral gate insulating film 215 may include a silicon oxide film, a silicon oxynitride film, a high dielectric constant insulating film having a higher dielectric constant than a dielectric constant of the silicon oxide film, or a combination thereof. The high dielectric constant insulating film may include, but is not limited to, at least one from among, for example, metal oxide, metal oxynitride, metal silicon oxide, and metal silicon oxynitride.

Each of the peripheral lower conductive pattern 223 and the peripheral upper conductive pattern 225 may include a conductive material. For example, each of the peripheral lower conductive pattern 223 and the peripheral upper conductive pattern 225 may include at least one from among a doped semiconductor material, conductive metal nitride, conductive metal silicon nitride, metal carbonitride, conductive metal silicide, conductive metal oxide, two-dimensional material (2D material), metal, and metal alloy. The peripheral gate structure PG is shown as including a plurality of conductive patterns. However, embodiments of the present disclosure are not limited thereto.

In a semiconductor memory device according to some embodiments, the two-dimensional material may be a metallic material and/or a semiconductor material. The two-dimensional material may include two-dimensional allotrope or two-dimensional compound. For example, the two-dimensional material may include, but is not limited to, at least one from among graphene, molybdenum disulfide (MoS₂), molybdenum diselenide (MoSe₂), tungsten diselenide (WSe₂), and tungsten disulfide (WS₂). That is, the above-described two-dimensional materials are only listed by way of example. The two-dimensional material that may be included in the semiconductor device according to embodiments of the present disclosure is not limited to the above-described materials.

A first peripheral lower insulating film 227 and a second peripheral lower insulating film 228 may be disposed on the substrate 100. Each of the first peripheral lower insulating film 227 and the second peripheral lower insulating film 228 may be made of an insulating material.

A first peripheral wiring line 241a and a peripheral contact plug 241b may be disposed within the first peripheral lower insulating film 227 and the second peripheral lower insulating film 228. Although the first peripheral wiring line 241a and the peripheral contact plug 241b are shown as different films, embodiments of the present disclosure are not limited thereto. A boundary between the first peripheral wiring line 241a and the peripheral contact plug 241b may not be defined. Each of the first peripheral wiring line 241a and the peripheral contact plug 241b may include a conductive material.

A first peripheral upper insulating film 261 and a second peripheral upper insulating film 262 may be disposed on the first peripheral wiring line 241a and the peripheral contact plug 241b. Each of the first peripheral upper insulating film 261 and the second peripheral upper insulating film 262 may be made of an insulating material.

A second peripheral wiring line 243 and a peripheral via plug 242 may be disposed on the first peripheral wiring line 241a. The peripheral via plug 242 may be disposed within the first peripheral upper insulating film 261. The second peripheral wiring line 243 may be disposed within the second peripheral upper insulating film 262.

The second peripheral wiring line 243 and the peripheral via plug 242 may be connected to the first peripheral wiring line 241a. Each of the second peripheral wiring line 243 and the peripheral via plug 242 may include a conductive material. The second peripheral wiring line 243 and the peripheral via plug 242 are shown as different films. However, embodiments of the present disclosure are not limited thereto. A boundary between the second peripheral wiring line 243 and the peripheral via plug 242 may not be defined.

A third peripheral upper insulating film 263, a fourth peripheral upper insulating film 264, and a fifth peripheral upper insulating film 265 may be sequentially disposed on the second peripheral wiring line 243. Each of the third peripheral upper insulating film 263, the fourth peripheral upper insulating film 264, and the fifth peripheral upper insulating film 265 may be made of an insulating material.

The fourth peripheral upper insulating film 264 may be made of an insulating material different from an insulating material of each of the third peripheral upper insulating film 263 and the fifth peripheral upper insulating film 265. For example, the fourth peripheral upper insulating film 264 may be made of an oxide-based insulating material, and each of the third peripheral upper insulating film 263 and the fifth peripheral upper insulating film 265 may be made of a nitride-based insulating material. However, embodiments of the present disclosure are not limited thereto.

A cell connection plug 244 may be disposed within the third peripheral upper insulating film 263, the fourth peripheral upper insulating film 264, and the fifth peripheral upper insulating film 265. The cell connection plug 244 may be connected to the second peripheral wiring line 243. The cell connection plug 244 may include a conductive material. According to embodiments, the cell connection plug 244 may be disposed in a peripheral upper insulating film that is a single film.

The bit-lines BL may be disposed on the peripheral gate structure PG. More specifically, the bit-lines BL may be disposed on the fifth peripheral upper insulating film 265. For example, the bit-lines BL may contact the fifth peripheral upper insulating film 265.

The bit-line BL may extend in an elongated manner in a second direction D2. Adjacent ones of the bit-lines BL may be spaced apart from each other in a first direction D1. The bit-line BL may include a long sidewall extending in the second direction D2 and a short sidewall extending in the first direction D1.

According to embodiments, each bit-line BL may extend from the cell array area to the peripheral circuit area. An end of each bit-line BL may be disposed on the peripheral circuit area of the substrate 100.

Each bit-line BL may be disposed on the cell connection plug 244. Each bit-line BL may include at least one from among, for example, doped semiconductor material, conductive metal nitride, conductive metal silicon nitride, metal carbonitride, conductive metal silicide, conductive metal oxide, two-dimensional material, metal, and metal alloy. Although each bit-line BL is shown as being embodied as a single film, embodiments of the present disclosure are not limited thereto.

A cell lower insulating film 171 may be disposed on the fifth peripheral upper insulating film 265. The cell lower insulating film 171 may be disposed between the bit-lines BL spaced apart from each other in the first direction D1. The cell lower insulating film 171 may be made of an insulating material.

The protruding insulating pattern 175 may be disposed on the bit-line BL and the cell lower insulating film 171. A cell lower etch stop film 173 may be disposed between the protruding insulating pattern 175 and the cell lower insulating film 171. Further, the cell lower etch stop film 173 may be disposed between the protruding insulating pattern 175 and the bit-line BL.

Each of the protruding insulating pattern 175 and the cell lower etch stop film 173 may be made of an insulating material. The cell lower etch stop film 173 may include a material having an etch selectivity relative to that of the protruding insulating pattern 175. For example, the protruding insulating pattern 175 may be made of an oxide-based insulating material. However, embodiments of the present disclosure are not limited thereto. According to embodiments, the cell lower etch stop film 173 may not be disposed between the protruding insulating pattern 175 and the cell lower insulating film 171.

The protruding insulating pattern 175 may include a plurality of channel trenches CH_T. Each channel trench CH_T may extend in an elongated manner in the first direction D1. Adjacent ones of the channel trenches CH_T may be spaced apart from each other in the second direction D2.

Each channel trench CH_T intersects the bit-line BL. One channel trench CH_T may expose a plurality of bit-lines BL adjacent to each other in the first direction D1.

A bottom surface of each channel trench CH_T may be defined by the bit-line BL and the cell lower insulating film 171. A sidewall of each channel trench CH_T may be defined by the protruding insulating pattern 175 and the cell lower etch stop film 173. At least a portion of the sidewall of the channel trench CH_T may be a sidewall 175SW of the protruding insulating pattern 175. When the cell lower etch stop film 173 is not disposed, the sidewall of each channel trench CH_T may be defined by the protruding insulating pattern 175.

The channel structure AP_ST may be disposed on each bit-line BL. The plurality of channel structures AP_ST may be connected to one bit-line BL. The plurality of channel structure AP_ST may be directly connected to the bit-line BL. The plurality of channel structures AP_ST disposed on one bit-line BL may be spaced apart from each other in the second direction D2.

The channel structure AP_ST may be disposed within a channel trench CH_T extending in the first direction D1. A plurality of channel structures AP_ST may be disposed within one channel trench CH_T. The plurality of channel structures AP_ST disposed within the channel trench CH_T may be spaced apart from each other in the first direction D1.

For example, the channel structure AP_ST may be arranged two-dimensionally along the first direction D1 and the second direction D2 that intersect each other.

The channel structure AP_ST may extend along a sidewall and a bottom surface of the channel trench CH_T. In a cross-sectional view as cut in the second direction D2, the channel structure AP_ST may have a “U” shape.

The channel structure AP_ST may include a horizontal portion AP_STH, a first vertical portion AP_STV1, and a second vertical portion AP_STV2. The first vertical portion AP_STV1 of the channel structure AP_ST and the second vertical portion AP_STV2 of the channel structure AP_ST may protrude in the third direction D3 from the horizontal portion AP_STH of the channel structure AP_ST.

The horizontal portion AP_STH of the channel structure AP_ST may extend along the bottom surface of the channel trench CH_T. In a cross-sectional view as cut in the second direction D2, the horizontal portion AP_STH of the channel structure AP_ST may extend along the upper surface of the bit-line BL. The horizontal portion AP_STH of the channel structure AP_ST may be connected to the bit-line BL. For example, the horizontal portion AP_STH of the channel structure AP_ST may contact the upper surface of the bit-line BL.

The first vertical portion AP_STV1 of the channel structure AP_ST and the second vertical portion AP_STV2 of the channel structure AP_ST may extend along the sidewall of the channel trench CH_T. In the cross-sectional view as cut in the second direction D2, each of the first vertical portion AP_STV1 of the channel structure AP_ST and the second vertical portion AP_STV2 of the channel structure AP_ST may extend along a sidewall of the liner film 177 as described below.

The channel structure AP_ST may include an oxide semiconductor material. For example, the channel structure AP_ST may include a metal oxide. The metal oxide may include, for example, one of indium gallium zinc oxide (IGZO), indium zinc oxide (IZO) doped with impurities, indium oxide (InO), zinc oxide (ZnO), gallium oxide (GaO), and tin oxide (SnO), aluminum zinc oxide (AZO), and indium tin oxide (ITO). In indium zinc oxide (IZO) doped with the impurities, the doped impurity may include at least one from among, for example, magnesium (Mg), strontium (Sr), barium (Ba), scandium (Sc), yttrium (Y), lanthanum (La), titanium (Ti), zirconium (Zr), hafnium (Hf), aluminum (Al), tin (Sn), and tantalum (Ta).

The channel structure AP_ST may include a first channel pattern AP1, a second channel pattern AP2, and a connection channel pattern AP_CP. The connection channel pattern AP_CP may connect the first channel pattern AP1 and the second channel pattern AP2 to each other. The first channel pattern AP1 and the second channel pattern AP2 may be spaced apart from each other in the second direction D2.

The first channel pattern AP1, the second channel pattern AP2, and the connection channel pattern AP_CP may be disposed on the bit-line BL. The first channel pattern AP1, the second channel pattern AP2, and the connection channel pattern AP_CP may be connected to the bit-line BL. The first channel pattern AP1, the second channel pattern AP2, and the connection channel pattern AP_CP may be in direct contact with the upper surface of the bit-line BL.

The first channel pattern AP1 may include a portion of the horizontal portion AP_STH of the channel structure AP_ST and the first vertical portion AP_STV1 of the channel structure AP_ST. The portion of the horizontal portion AP_STH of the channel structure AP_ST may be a horizontal portion of the first channel pattern AP1. The first vertical portion AP_STV1 of the channel structure AP_ST may be a vertical portion of the first channel pattern AP1.

The second channel pattern AP2 may include another portion of the horizontal portion AP_STH of the channel structure AP_ST and the second vertical portion AP_STV2 of the channel structure AP_ST. The another portion of the horizontal portion AP_STH of the channel structure AP_ST may be a horizontal portion of the second channel pattern AP2. The second vertical portion AP_STV2 of the channel structure AP_ST may be a vertical portion of the second channel pattern AP2.

The connection channel pattern AP_CP may include the remainder of the horizontal portion AP_STH of the channel structure AP_ST. In other words, the connection channel pattern AP_CP includes the remainder of the horizontal portion AP_STH of the channel structure AP_ST, other than a horizontal portion included in the first channel pattern AP1 and a horizontal portion included in the second channel pattern AP2.

Based on the first word-line WL1 and the second word-line WL2, which will be described later, the first channel pattern AP1, the second channel pattern AP2, and the connection channel pattern AP_CP may be distinguished from each other. For example, in FIG. 4, the first word-line WL1 is described by way of example. The first word-line WL1 may include an inner sidewall facing the sidewall 175SW of the protruding insulating pattern 175, and an outer sidewall that is opposite to the inner sidewall in the second direction D2. A boundary between the first channel pattern AP1 and the connection channel pattern AP_CP may coincide with a virtual extension line of the outer sidewall of the first word-line WL1 extending in the third direction D3. In another example, the second word-line WL2 may include an inner sidewall facing the sidewall 175SW of the protruding insulating pattern 175, and an outer sidewall that is opposite to the inner sidewall in the second direction D2. A boundary between the second channel pattern AP2 and the connection channel pattern AP_CP may coincide with a virtual extension line of the outer sidewall of the second word-line WL2 extending in the third direction D3.

In the semiconductor memory device according to some embodiments, each of the first channel pattern AP1, the second channel pattern AP2, and the connection channel pattern AP_CP may include a metal oxide.

The liner film 177 may extend along at least a portion of the sidewall 175SW of the protruding insulating pattern 175. More specifically, the liner film 177 may extend along a sidewall of the cell lower etch stop film 173 and the sidewall 175SW of the protruding insulating pattern 175. The liner film 177 may be disposed on the bit-line BL. The liner film 177 may contact the upper surface of the bit-line BL.

The liner film 177 may be disposed between the protruding insulating pattern 175 and the first channel pattern AP1. The liner film 177 may be disposed between the protruding insulating pattern 175 and the second channel pattern AP2. A portion of the liner film 177 may be disposed between the protruding insulating pattern 175 and the first channel pattern AP1, and another portion of the liner film 177 may be disposed between the protruding insulating pattern 175 and the landing pad LP, which will be described later. Additionally, a portion of the liner film 177 may be disposed between the protruding insulating pattern 175 and the second channel pattern AP2, and another portion of the liner film 177 may be disposed between the protruding insulating pattern 175 and the landing pad LP.

The liner film 177 may entirely cover the sidewall 175SW of the protruding insulating pattern 175. In this case, an upper surface 177US of the liner film 177 may be at the same vertical level as a vertical level of the upper surface 175US of the protruding insulating pattern 175. As used herein, “the same” means not only being completely identical but also including a minute difference that may occur due to a margin in a process, etc.

The upper surface 177US of the liner film 177 may be at a higher vertical level than a vertical level of each of the upper surface AP1_US of the first channel pattern AP1 and the upper surface AP2_US of the second channel pattern AP2. That is, a vertical distance between the upper surface of bit-line BL and the upper surface 177US of the liner film 177 may be larger than a vertical distance between the upper surface of bit-line BL and each of the upper surface AP1_US of the first channel pattern AP1 and the upper surface AP2_US of the second channel pattern AP2.

In the second direction D2, the protruding insulating pattern 175, the liner film 177, and the first channel pattern AP1 may be arranged sequentially. In the second direction D2, the protruding insulating pattern 175, the liner film 177, and the second channel pattern AP2 may be arranged sequentially.

The liner film 177 may contain fluorine (F). The liner film 177 may be embodied as a layer containing fluorine. The liner film 177 may be formed by performing fluorine surface treatment on the protruding insulating pattern 175. The fluorine surface treatment may include fluorine plasma, a clean process including fluorine (e.g., an HF clean process), chemical vapor deposition (CVD), or physical vapor deposition (PVD).

While the fluorine surface treatment is in progress, a native oxide film formed on the bit-line BL may be removed. Accordingly, a contact resistance between the bit-line BL and the channel structure AP_ST may be lowered. When the liner film 177 containing the fluorine is disposed between the protruding insulating pattern 175 and the channel structure AP_ST, a quality of an interface between the protruding insulating pattern 175 and the channel structure AP_ST may be improved. For example, when the liner film 177 is disposed between the protruding insulating pattern 175 and the channel structure AP_ST, a trap site at which electrons are trapped may be reduced. Accordingly, mobility of the electrons contained in each of the first channel pattern AP1 and the second channel pattern AP2 may be improved. As a result, the resistance of the channel structure AP_ST may be lowered. The resistance of the channel structure AP_ST may be lowered due to the liner film 177, and the contact resistance between the bit-line BL and the channel structure AP_ST may be lowered due to the liner film 177, so that on-current (iₒₙ) may be improved.

The first word-line WL1 and the second word-line WL2 may be disposed on the channel structure AP_ST. The first word-line WL1 and the second word-line WL2 may be disposed in the channel trench CH_T.

Each of the first word-line WL1 and the second word-line WL2 may extend in the first direction D1. The first word-lines WL1 and the second word-lines WL2 may be alternately arranged with each other in the second direction D2. The first word-line WL1 may be spaced apart from the second word-line WL2 in the second direction D2.

The first word-line WL1 and the second word-line WL2 may be spaced apart from the bit-line BL in the third direction D3. The first word-line WL1 and the second word-line WL2 may intersect the bit-line BL.

The first word-line WL1 and the second word-line WL2 may be disposed on the horizontal portion AP_STH of the channel structure. The first word-line WL1 and the second word-line WL2 may be disposed between the first vertical portion AP_STV1 of the channel structure AP_ST and the second vertical portion AP_STV2 of the channel structure AP_ST.

The first word-line WL1 may be disposed on the first channel pattern AP1. The second word-line WL2 may be disposed on the second channel pattern AP2. The first word-line WL1 and the second word-line WL2 may be disposed between the first channel pattern AP1 and the second channel pattern AP2. The first channel pattern AP1 may be disposed closer to the first word-line WL1 than to the second word-line WL2. The second channel pattern AP2 may be disposed closer to the second word-line WL2 than to the first word-line WL1.

Each of the first word-line WL1 and the second word-line WL2 may have a width in the second direction D2 (see FIG. 1). A width of a portion the first word-line WL1 that overlaps the channel structure AP_ST in the third direction D3 may be different from a width of a portion the first word-line WL1 that does not overlap the channel structure AP_ST. A width of a portion of the second word-line WL2 that overlaps the channel structure AP_ST in the third direction D3 may be different from a width of a portion of the second word-line WL2 that does not overlap the channel structure AP_ST.

For example, as shown in FIG. 1, each of the first word-line WL1 and the second word-line WL2 may include a first portion WLa and a second portion WLb. A width in the second direction D2 of the first portion WLa of the word-line may be smaller than a width in the second direction of the second portion WLb of the word-line. For example, the first portion WLa of the word-line may be disposed on the channel structure AP_ST. The first portion WLa of the word-line may be disposed on the first channel pattern AP1 and the second channel pattern AP2.

Each of the first word-line WL1 and the second word-line WL2 may include first portions WLa and second portions WLb alternately arranged with each other along the first direction D1. Each channel structure AP_ST may be disposed between the second portions WLb of the word-line adjacent to each other in the first direction D1. Each of the first active patterns AP1 may be disposed between the second portions WLb of the first word-line WL1 adjacent to each other in the first direction D1. Each of the second active patterns AP2 may be disposed between the second portions WLb of the second word-line WL2 adjacent to each other in the first direction D1.

The channel structure AP_ST is not disposed under the second portion WLb of the word-line. A vertical length of the first portion WLa of the word-line is smaller than a vertical length of the second portion WLb of the word-line.

Each of the first word lines WL1 and second word lines WL2 may include a conductive material such as, for example, at least one from among doped polysilicon, conductive metal nitride, conductive metal silicon nitride, metal carbonitride, conductive metal silicide, conductive metal oxide, two-dimensional material, metal, and metal alloy.

Each of the first word-lines WL1 and second word lines WL2 may include an upper surface WL_US and a lower surface WL BS that are opposite to each other in the third direction D3. The lower surface WL_BS of each of the first word-lines WL1 and second word lines WL2 may face the bit-line BL.

The upper surface WL_US of each of the first word-lines WL1 and second word lines WL2 may be flat. However, embodiments of the present disclosure are not limited thereto. The lower surface WL_BS of each of the first word-lines WL1 and second word lines WL2 may be flat. However, embodiments of the present disclosure are not limited thereto.

Based on the upper surface of the bit-line BL, a vertical level of the upper surface WL_US of each of the first word-lines WL1 and second word lines WL2 may be higher than a top level of each of the vertical portions (e.g.,. the first vertical portion AP_STV1 and the second vertical portion AP_STV2) of the channel structure AP_ST. A top level of each of the channel patterns (e.g., the first channel pattern AP1 and the second channel pattern AP2) may be the top level of each of the vertical portions (e.g.,. the first vertical portion AP_STV1 and the second vertical portion AP_STV2) of the channel structure AP_ST. That is, a vertical length H1 from the upper surface of the bit-line BL to the top level of each of the vertical portions (e.g., the first vertical portion AP_STV1 and the second vertical portion AP_STV2) of the channel structure AP_ST may be smaller than a vertical length H2 from the upper surface of the bit-line BL to the upper surface WL_US of each of the first word-lines WL1 and second word lines WL2.

A gate insulating film GOX may be disposed between the first word-line WL1 and the channel structure AP_ST and between the second word-line WL2 and the channel structure AP_ST. The gate insulating film GOX may be disposed between the first word-line WL1 and the first active pattern AP1 and between the second word-line WL2 and the second active pattern AP2. The gate insulating film GOX may extend in the first direction D1 in a parallel manner to the first word-line WL1 and the second word-line WL2.

The gate insulating film GOX may extend along the first vertical portion AP_STV1 of the channel structure AP_ST. The gate insulating film GOX may extend along the second vertical portion AP_STV2 of the channel structure AP_ST. In the semiconductor memory device according to some embodiments, the gate insulating film GOX may not be disposed on a portion of the horizontal portion AP_STH of the channel structure AP_ST that does not overlap the first word-line WL1 and the second word-line WL2 in the third direction D3. In a cross-sectional view, the gate insulating film GOX between the first word-line WL1 and the channel structure AP_ST may be isolated from the gate insulating film GOX between the second word-line WL2 and the channel structure AP_ST.

The gate insulating film GOX may include a silicon oxide film, a silicon oxynitride film, a high dielectric constant insulating film with a higher dielectric constant than that of the silicon oxide film, or a combination thereof.

A portion of the gate insulating film GOX may protrude in the third direction D3 beyond the upper surface WL_US of each of the first word-lines WL1 and second word lines WL2. A portion of the gate insulating film GOX may protrude in the third direction D3 beyond the top level of each of the vertical portions (e.g.,. the first vertical portion AP_STV1 and the second vertical portion AP_STV2) of the channel structure AP_ST.

A vertical length H4 from the upper surface of the bit-line BL to a top level GOX_UUS of the gate insulating film GOX may be larger than the vertical length H1 from the upper surface of the bit-line BL to the top level of each of the vertical portions (e.g.,. the first vertical portion AP_STV1 and the second vertical portion AP_STV2) of the channel structure AP_ST. The vertical length H4 from the upper surface of the bit-line BL to the top level GOX_UUS of the gate insulating film GOX may be larger than the vertical length H2 from the upper surface of the bit-line BL to the upper surface WL_US of each of the first word-lines WL1 and second word lines WL2. The vertical length H4 from the upper surface of the bit-line BL to the top level GOX_UUS of the gate insulating film GOX may be equal to a vertical length from the upper surface of the bit-line BL to the upper surface 177US of the liner film 177. However, embodiments of the present disclosure are not limited thereto.

A gate isolation pattern GSS may be disposed on the bit-line BL and the cell lower insulating film 171. The gate isolation pattern GSS may be disposed within the channel trench CH_T. The gate isolation pattern GSS may be disposed on the channel structure AP_ST, the first word-line WL1, and the second word-line WL2.

In the semiconductor memory device according to some embodiments, the gate isolation pattern GSS may contact the channel structure AP_ST. The gate isolation pattern GSS may be disposed on the connection channel pattern AP_CP. The gate isolation pattern GSS may contact the horizontal portion AP_STH of the channel structure AP_ST. The gate isolation pattern GSS may be spaced apart from the bit line BL in the third direction D3.

The gate isolation pattern GSS may be disposed between the first word-line WL1 and the second word-line WL2 adjacent to each other in the second direction D2. The first word-line WL1 and the second word-line WL2 may be isolated from each other via the gate isolation pattern GSS. The gate isolation pattern GSS may extend in the first direction D1 and between the first word-line WL1 and the second word-line WL2.

The first word-line WL1 may be disposed between the gate isolation pattern GSS and the channel structure AP_ST. The second word-line WL2 may be disposed between the gate isolation pattern GSS and the channel structure AP_ST. The first word-line WL1 may be disposed between the gate isolation pattern GSS and the first channel pattern AP1. The second word-line WL2 may be disposed between the gate isolation pattern GSS and the second channel pattern AP2.

The gate isolation pattern GSS may include a horizontal portion and a protrusion. The protrusion of the gate isolation pattern GSS may protrude in the third direction D3 from the horizontal portion of the gate isolation pattern GSS toward the bit-line BL. The protrusion of the gate isolation pattern GSS may be closer than the horizontal portion of the gate isolation pattern GSS to the bit-line BL.

The horizontal portion of the gate isolation pattern GSS may be disposed on the upper surface WL_US of each of the first word-lines WL1 and second word lines WL2. In a cross-sectional view, the gate isolation pattern GSS may have a “T” shape.

The gate isolation pattern GSS may include a gate isolation liner 151 and a gate isolation filling film 153. The gate isolation liner 151 may extend along the upper surface WL_US of each of the first word-lines WL1 and second word lines WL2 and the outer sidewall of each of the first word-lines WL1 and second word lines WL2. The gate isolation liner 151 may extend along the horizontal portion AP_STH of the channel structure AP_ST. The gate isolation liner 151 may contact the connection channel pattern AP_CP. The gate isolation liner 151 may extend along a portion of the gate insulating film GOX protruding upwardly beyond the upper surface WL_US of each of the first word-lines WL1 and second word lines WL2. According to embodiments, the gate isolation liner 151 may not extend along the portion of the gate insulating film GOX protruding beyond the upper surface WL_US of each of the first word-lines WL1 and second word lines WL2.

The gate isolation filling film 153 may be disposed on the gate isolation liner 151. The gate isolation filling film 153 may contact the gate isolation liner 151. In a cross-sectional view, the gate isolation filling film 153 may have a “T” shape. Each of the gate isolation liner 151 and the gate isolation filling film 153 may be made of an insulating material. According to embodiments, the gate isolation pattern GSS may be embodied as a single film.

Based on the upper surface of the bit-line BL, an upper surface GSS_US of the gate isolation pattern GSS may be located at the same vertical level as a vertical level of the upper surface of the protruding insulating pattern 175. However, embodiments of the present disclosure are not limited thereto.

The vertical length H3 from the upper surface of the bit-line BL to the upper surface GSS_US of the gate isolation pattern GSS may be larger than the vertical length H1 from the upper surface of the bit-line BL to the top level of the vertical portions (e.g.,. the first vertical portion AP_STV1 and the second vertical portion AP_STV2) of the channel structure AP_ST. The vertical length H3 from the upper surface of the bit-line BL to the upper surface GSS_US of the gate isolation pattern GSS may be larger than the vertical length H2 from the upper surface of the bit-line BL to the upper surface WL_US of each of the word-lines WL1 and WL2.

The vertical length H3 from the upper surface of the bit-line BL to the upper surface GSS_US of the gate isolation pattern GSS is shown to be equal to the vertical length H4 from the upper surface of the bit-line BL to the top level GOX_UUS of the gate insulating film GOX. However, embodiments of the present disclosure are not limited thereto.

The vertical length H3 from the upper surface of the bit-line BL to the upper surface GSS_US of gate isolation pattern GSS may be equal to the vertical length from the upper surface of the bit-line BL to the upper surface 177US of the liner film 177. However, embodiments of the present disclosure are not limited thereto.

The landing pads LP may be disposed on the channel structure AP_ST. The landing pads LP are connected to the first vertical portion AP_STV1 of the channel structure AP_ST and the second vertical portion AP_STV2 of the channel structure AP_ST.

The landing pads LP may be disposed on the first channel pattern AP1 and the second channel pattern AP2. The landing pads LP may be connected to the first channel pattern AP1 and the second channel pattern AP2. The landing pads LP may contact the liner film 177.

In a plan view, each of the landing pads LP may have various shapes such as circular, oval, rectangular, square, diamond, and hexagonal shapes.

The landing pad LP may include a horizontal landing pad LP_H and a protruding landing pad LP_P. The horizontal landing pad LP_H of the landing pad LP may be disposed on the upper surface 175US of the protruding insulating pattern 175, the upper surface 177US of the liner film 177, and the upper surface GSS_US of the gate isolation pattern GSS. The protruding landing pad LP_P of the landing pad LP may protrude in the third direction D3 from the horizontal landing pad LP_H of the landing pad LP toward the bit-line BL. The protruding landing pad LP_P may be disposed between the liner film 177 and the gate insulating film GOX.

Based on the upper surface of the bit-line BL, a vertical level of a bottom surface of the landing pad LP may be lower than a vertical level of the upper surface GSS_US of the gate isolation pattern GSS. In other words, the protruding landing pad LP_P of the landing pad LP may be disposed between the protruding insulating pattern 175 and the gate isolation pattern GSS. A vertical length from the upper surface of the bit-line BL to the bottom surface of the landing pad LP may be smaller than the vertical length from the upper surface of the bit-line BL to the top level GOX_UUS of the gate insulating film GOX.

Pad isolation insulating patterns 235 may be disposed between the landing pads LP.

In the plan view, the landing pads LP may be arranged in a matrix form along the first direction D1 and the second direction D2. The upper surface of the landing pads LP may be coplanar with the upper surface of the pad isolation insulating patterns 235. However, embodiments of the present disclosure are not limited thereto.

The landing pad LP includes a conductive material. The landing pad LP may include at least one from among, for example, doped polysilicon, conductive metal nitride, conductive metal silicon nitride, metal carbonitride, conductive metal silicide, conductive metal oxide, two-dimensional material, metal, and metal alloy.

The data storage patterns DSP may be respectively disposed on the landing pads LP. The data storage patterns DSP may be connected to the first vertical portion AP_STV1 of the channel structure AP_ST and the second vertical portion AP_STV2 of the channel structure AP_ST. The data storage patterns DSP may be connected to the first channel pattern AP1 and the second channel pattern AP2, respectively.

The data storage patterns DSP may be arranged in a matrix form along the first direction D1 and the second direction D2, as shown in FIG. 1. The data storage patterns DSP may entirely overlap or partially overlap the landing pads LP in the third direction D3, respectively. The data storage pattern DSP may contact an entirety or a portion of the upper surface of each of the landing pads LP.

In one example, the data storage pattern DSP may be at least one capacitor (e.g., a first capacitor and a second capacitor). The first channel pattern AP1 may be connected to a first capacitor of the data storage pattern DSP. The second channel pattern AP2 may be connected to a second capacitor of the data storage pattern DSP.

The data storage pattern DSP may include a storage electrode 251, a plate electrode 255, and a capacitor dielectric film 253 interposed between the storage electrode 251 and the plate electrode 255. In this case, the storage electrode 251 may contact the landing pad LP. In the plan view, the storage electrode 251 may have various shapes such as circular, oval, rectangular, square, diamond, and hexagonal shapes. The data storage pattern DSP may entirely overlap or partially overlap the landing pad LP. The data storage pattern DSP may contact an entirety or a portion of the upper surface of each of the landing pads LP. Each storage electrode 251 may extend through a cell upper etch stop film 247. The cell upper etch stop film 247 may be made of an insulating material.

Alternatively, each of the data storage patterns DSP may be embodied as a variable resistance pattern that may be switched between two resistance states under an electrical pulse applied to a memory element. For example, each of the data storage patterns DSP may include a phase-change material having a crystal state varying depending on an amount of current, perovskite compounds, transition metal oxides, magnetic materials, ferromagnetic materials, or antiferromagnetic materials.

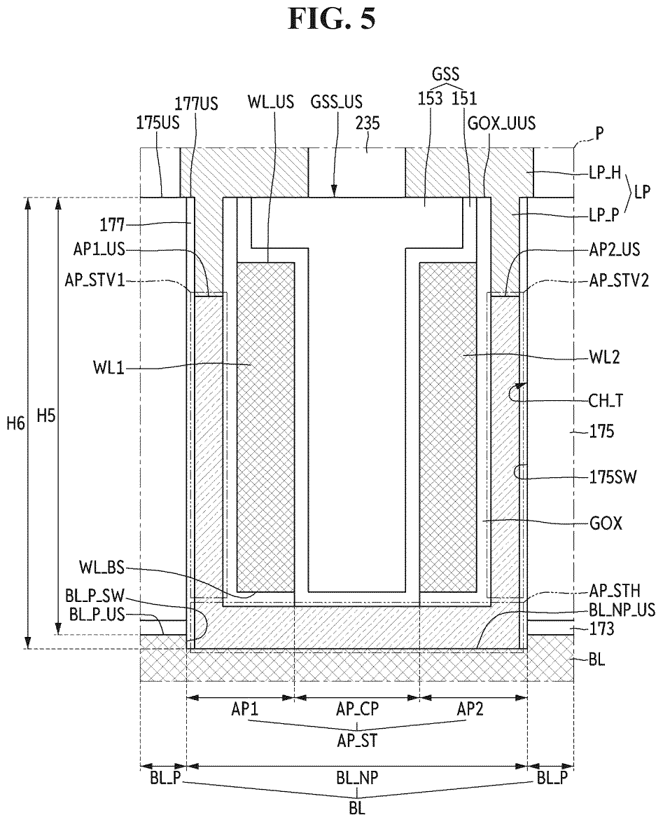

FIGS. 5 to 9 are diagrams for illustrating a semiconductor memory device according to some embodiments of the present disclosure. FIGS. 5 to 9 are enlarged views of a P portion of FIG. 2. For convenience of description, contents duplicate with what has been described above in FIGS. 1 to 4 may be briefly described or repeated descriptions thereof may be omitted.

Referring to FIG. 5, the bit-line BL may include a protruding portion BL_P and a non-protruding portion BL_NP. The protruding portion BL_P may be an area that overlaps with the protruding insulating pattern 175 in the third direction D3. The non-protruding portion BL_NP may be a portion that does not overlap with the protruding insulating pattern 175 in the third direction D3. The channel structure AP_ST may be disposed on the non-protruding portion BL_NP.

The protruding portion BL_P may protrude in the third direction D3 beyond the non-protruding portion BL_NP. For example, an upper surface BL_P_US of the protruding portion BL_P may be at a higher vertical level than a vertical level of an upper surface BL_NP_US of the non-protruding portion BL_NP. The cell lower etch stop film 173 and the protruding insulating pattern 175 may be disposed on the protruding portion BL_P.

A sidewall BL_P_SW of the protruding portion BL_P may be aligned with (e.g., coplanar with) the sidewall 175SW of the protruding insulating pattern 175. However, embodiments of the present disclosure are not limited thereto. According to embodiments, the sidewall BL_P_SW of the protruding portion BL_P may be a rounded curved surface. That is, the sidewall BL_P_SW of the protruding portion BL_P may be a concavely or convexly curved surface.

The liner film 177 may cover a portion of the sidewall BL_P_SW of the protruding portion BL_P. The liner film 177 may extend from a portion of the sidewall BL_P_SW of the protruding portion BL_P to the sidewall 175SW of the protruding insulating pattern 175. The liner film 177 may overlap a portion of the protruding portion BL_P in the first direction D1.

The liner film 177 may contact the upper surface BL_NP_US of the non-protruding portion BL_NP. The liner film 177 may be disposed on the upper surface BL_NP_US of the non-protruding portion BL_NP.

A vertical length H5 between the upper surface BL_P_US of the protruding portion BL_P and the upper surface 177US of the liner film 177 may be smaller than a vertical length H6 between the upper surface 177US of the liner film 177 and the upper surface BL_NP_US of the non-protruding portion BL_NP. In other words, a length from the upper surface BL_P_US of the protruding portion BL_P to the upper surface 177US of the liner film 177 may be smaller than a length from the upper surface BL_NP_US of the non-protruding portion BL_NP to the upper surface 177US of the liner film 177.

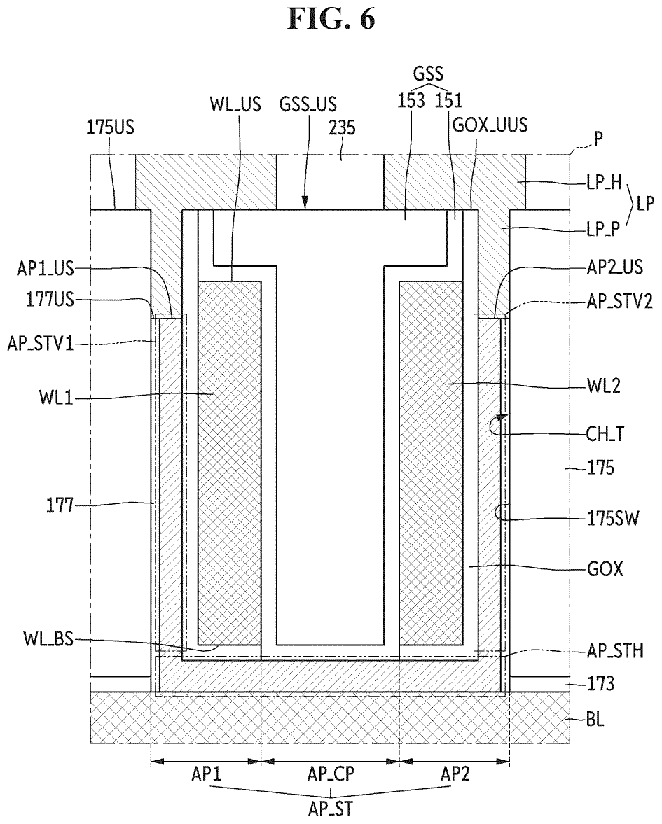

Referring to FIG. 6, the liner film 177 may extend along a portion of the sidewall 175SW of the protruding insulating pattern 175. The upper surface 177US of the liner film 177 may be coplanar with the upper surface AP1_US of the first channel pattern AP1 and the upper surface AP2_US of the second channel pattern AP2.

Based on the upper surface of the bit-line BL, each of the upper surface AP1_US of the first channel pattern AP1 and the upper surface AP2_US of the second channel pattern AP2 may be at the same vertical level as a vertical level of the upper surface 177US of the liner film 177. In some embodiments, each of the upper surface AP1_US of the first channel pattern AP1 and the upper surface AP2_US of the second channel pattern AP2 may be at a higher vertical level than the vertical level of the upper surface 177US of the liner film 177.

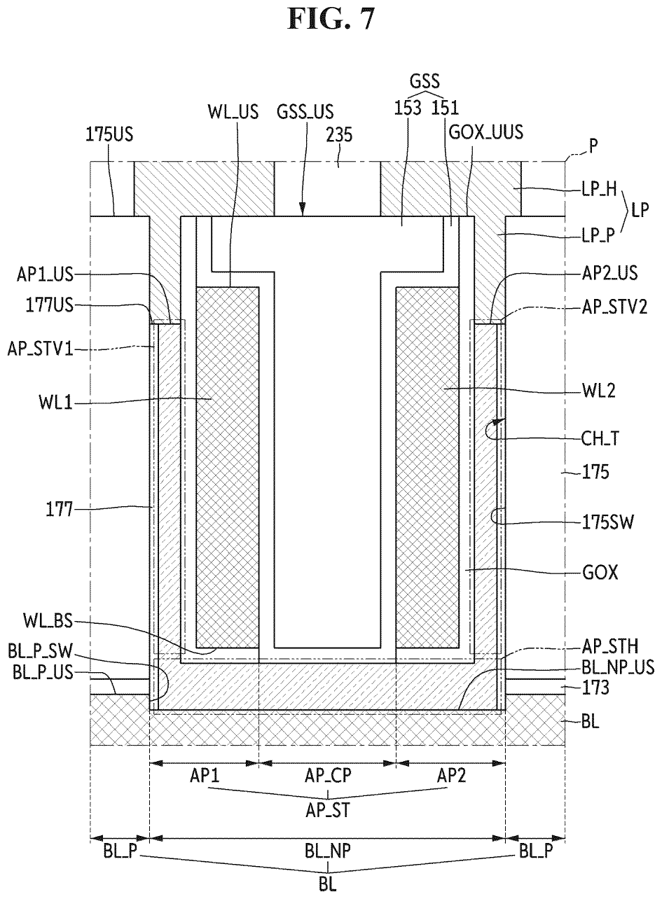

Referring to FIG. 7, the liner film 177 may extend along a portion of the sidewall BL_P_SW of the protruding portion BL_P of the bit-line BL and a portion of the sidewall 175SW of the protruding insulating pattern 175. The liner film 177 may cover the portion of the sidewall BL_P_SW of the protruding portion BL_P, a portion of the cell lower etch stop film 173, and a portion of the sidewall 175SW of the protruding insulating pattern 175. The liner film 177 may simultaneously contact the portion of the sidewall BL_P_SW of the protruding portion BL_P, the cell lower etch stop film 173, the protruding insulating pattern 175, and the channel patterns (e.g., the first channel pattern AP1 and the second channel pattern AP2).

The liner film 177 may extend from the upper surface BL_NP_US of the non-protruding portion BL_NP to the upper surface AP1_US of the first channel pattern AP1. The upper surface 177US of the liner film 177 may be coplanar with each of the upper surface AP1_US of the first channel pattern AP1 and the upper surface AP2_US of the second channel pattern AP2. Although not shown, in some embodiments, each of the upper surface AP1_US of the first channel pattern AP1 and the upper surface AP2_US of the second channel pattern AP2 may be at a higher vertical level than a vertical level of the upper surface 177US of the liner film 177.

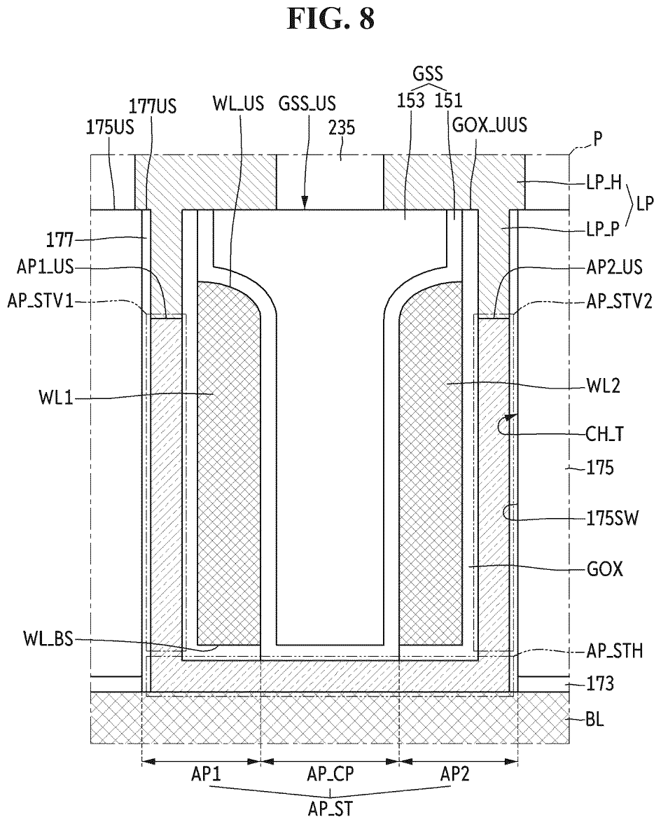

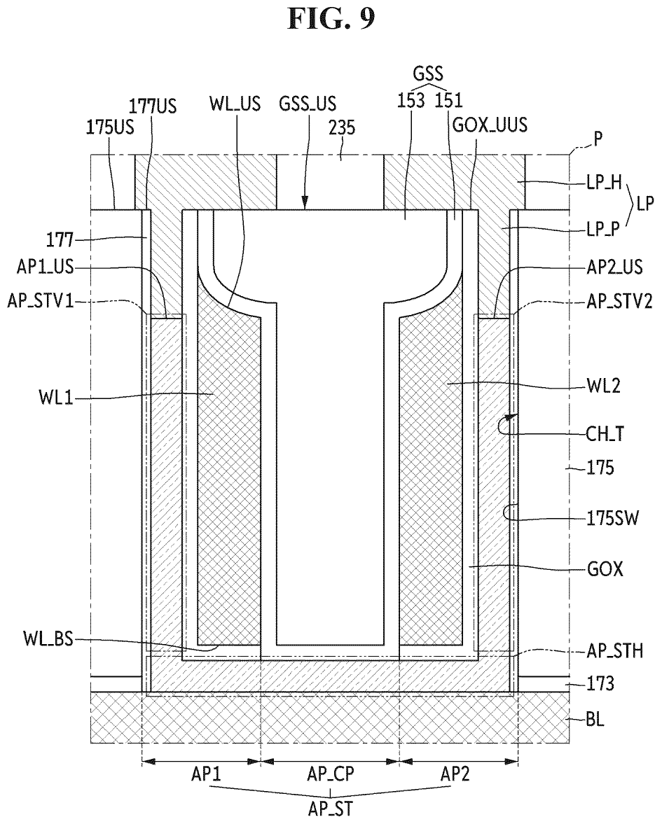

Referring to FIG. 8, the upper surface WL_US of each of the first word-lines WL1 and second word lines WL2 may be convexly rounded. Referring to FIG. 9, the upper surface WL_US of each of the first word-lines WL1 and second word lines WL2 may be concavely rounded.

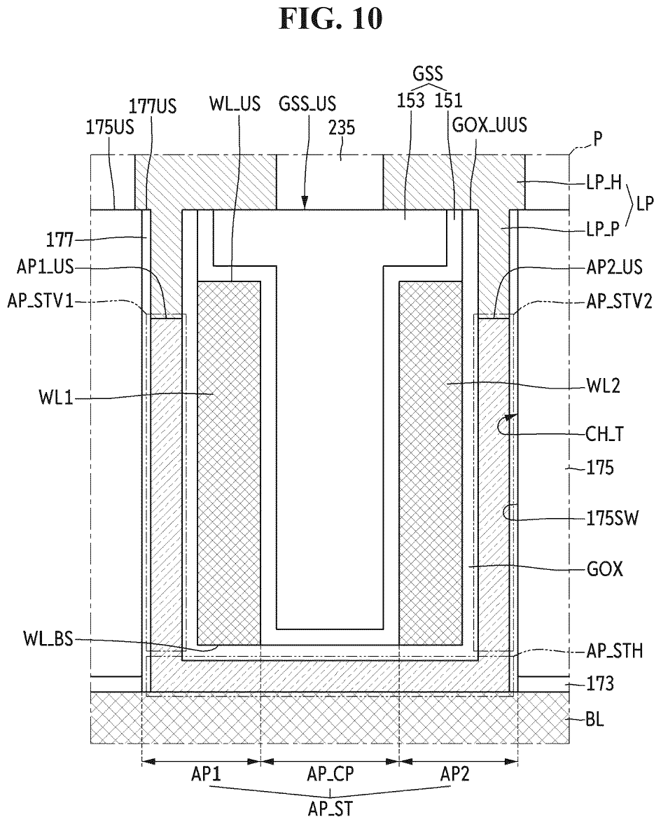

FIG. 10 is a diagram for illustrating a semiconductor memory device according to some embodiments of the present disclosure. For convenience of description, contents duplicate with what has been described above in FIGS. 1 to 4 may be briefly described or repeated descriptions may be omitted.

Referring to FIG. 10, in the semiconductor memory device according to some embodiments, the gate isolation pattern GSS does not contact the channel structure AP_ST.

A portion of the gate insulating film GOX may be disposed between the gate isolation pattern GSS and the channel structure AP_ST. In a cross-sectional view, a portion of the gate insulating film GOX between the first word-line WL1 and the channel structure AP_ST may be connected to a portion of the gate insulating film GOX between the second word-line WL2 and the channel structure AP_ST.

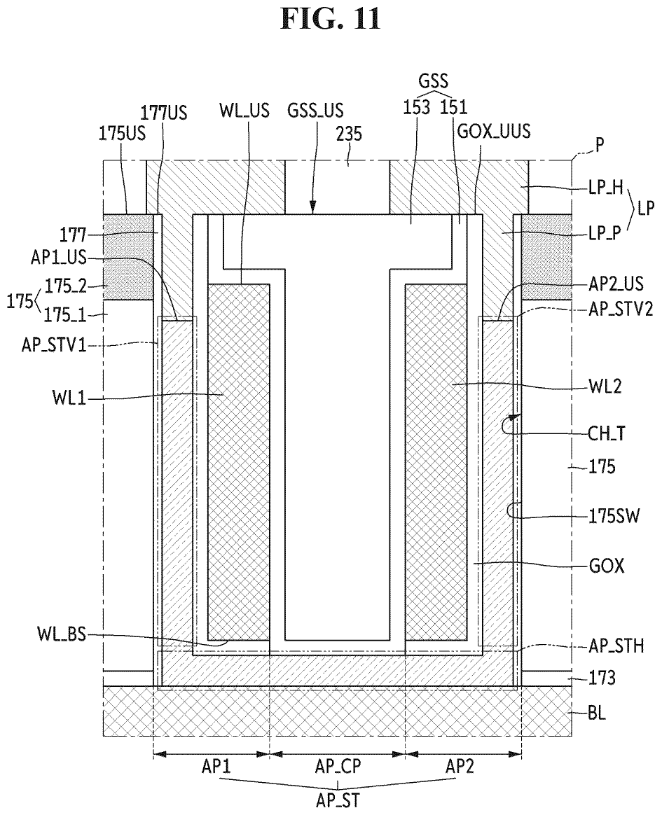

FIG. 11 is a diagram for illustrating a semiconductor memory device according to some embodiments of the present disclosure. For convenience of description, contents duplicate with what has been described above in FIGS. 1 to 4 may be briefly described or repeated descriptions thereof may be omitted.

Referring to FIG. 11, the protruding insulating pattern 175 may include a first mold insulating film 175_1 and a second mold insulating film 175_2.

The first mold insulating film 175_1 may be disposed on the cell lower etch stop film 173. The second mold insulating film 175_2 may be disposed on the first mold insulating film 175_1.

The first mold insulating film 175_1 and the second mold insulating film 175_2 may include different materials from each other. For example, the first mold insulating film 175_1 may include a silicon oxide-based insulating material, such as silicon oxide. The second mold insulating film 175_2 may include a silicon nitride-based insulating material, such as silicon nitride.

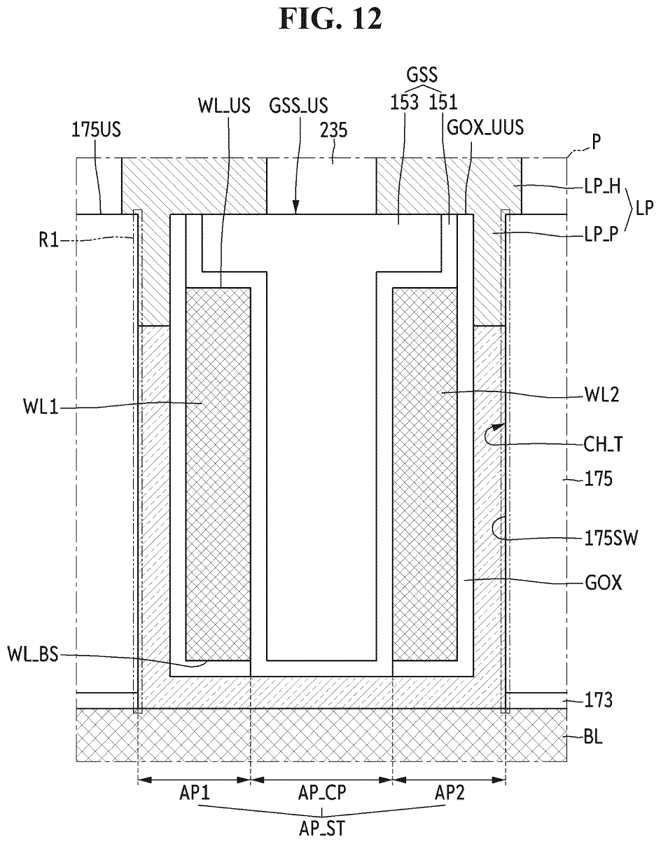

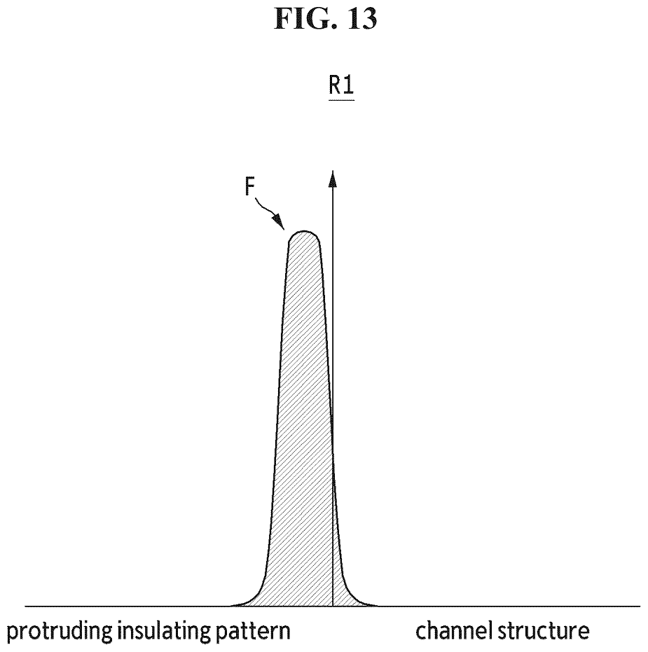

FIG. 12 and FIG. 13 are diagrams for illustrating a semiconductor memory device according to some embodiments of the present disclosure.

Referring to FIG. 12 and FIG. 13, in some embodiments, the semiconductor memory device may not include the liner film 177 containing fluorine. However, the protruding insulating pattern 175 may contain fluorine.

FIG. 13 is a graph showing a concentration of fluorine at a boundary of the protruding insulating pattern 175 and the channel structure AP_ST in an area R1. A horizontal axis represents an area of the protruding insulating pattern 175 and an area of the channel structure AP_ST. A vertical axis represents a fluorine concentration (/cm³).

The concentration of fluorine in the area of the protruding insulating pattern 175 may increase as the area extends toward the boundary between protruding insulating pattern 175 and the channel structure AP_ST. In other words, the protruding insulating pattern 175 may be doped with fluorine.

In some embodiments, fluorine may accumulate only in the protruding insulating pattern 175. Specifically, unlike what is shown in FIG. 13 where a portion of fluorine is detected in the channel structure AP_ST, fluorine may only be detected in the area of the protruding insulating pattern 175.

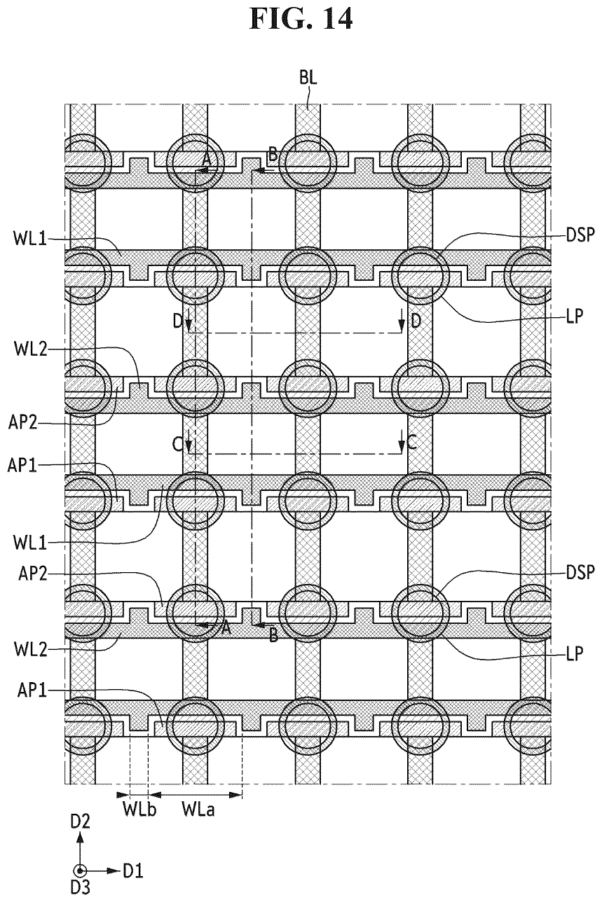

FIGS. 14 to 17 are diagrams for illustrating a semiconductor memory device according to some embodiments of the present disclosure. For convenience of description, contents duplicate with what has been described above in FIGS. 1 to 4 may be briefly described or repeated descriptions thereof may be omitted.

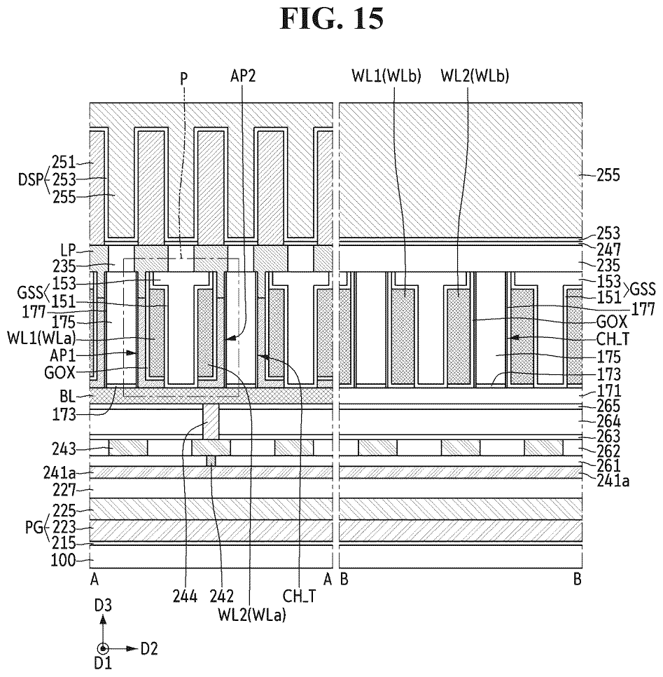

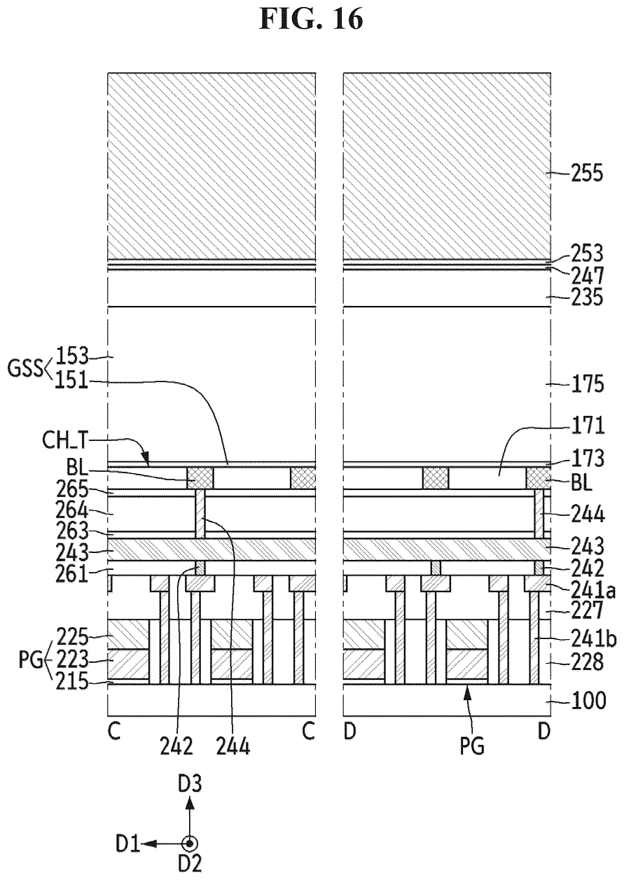

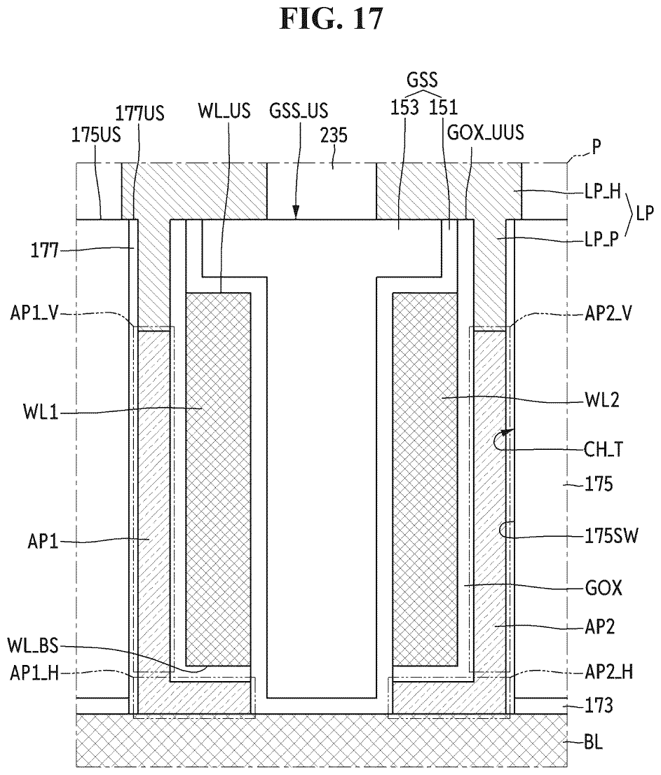

For reference, FIG. 14 is a layout diagram for illustrating a semiconductor memory device according to some embodiments. FIG. 15 is a cross-sectional view cut along lines A-A and B-B of FIG. 14. FIG. 16 is a cross-sectional view cut along C-C and D-D in FIG. 14. FIG. 17 is an enlarged view of a P portion of FIG. 15.

Referring to FIGS. 14 to 17, in the semiconductor memory device according to some embodiments, the first channel pattern AP1 and the second channel pattern AP2 spaced apart from each other in the second direction D2 are not connected to each other within the channel trench CH_T.

Each of the first channel pattern AP1 and the second channel pattern AP2 may include a metal oxide.

The first channel pattern AP1 may include a horizontal portion AP1_H extending along the upper surface of the bit-line BL and a vertical portion AP1_V extending along the sidewall 175SW of the protruding insulating pattern 175. The vertical portion AP1_V of the first channel pattern AP1 may protrude from the horizontal portion AP1_H of the first channel pattern AP1 in the third direction D3.

The second channel pattern AP2 may include a horizontal portion AP2_H extending along the upper surface of the bit-line BL and a vertical portion AP2_V extending along the sidewall 175SW of the protruding insulating pattern. The vertical portion AP2_V of the second channel pattern may protrude from the horizontal portion AP2_H of the second channel pattern in the third direction D3.

The gate isolation pattern GSS may contact the bit-line BL. The horizontal portion AP2_H of the first channel pattern and the horizontal portion AP1_H of the second channel pattern may be spatially isolated from each other via the gate isolation pattern GSS. The gate isolation liner 151 may contact the bit-line BL.

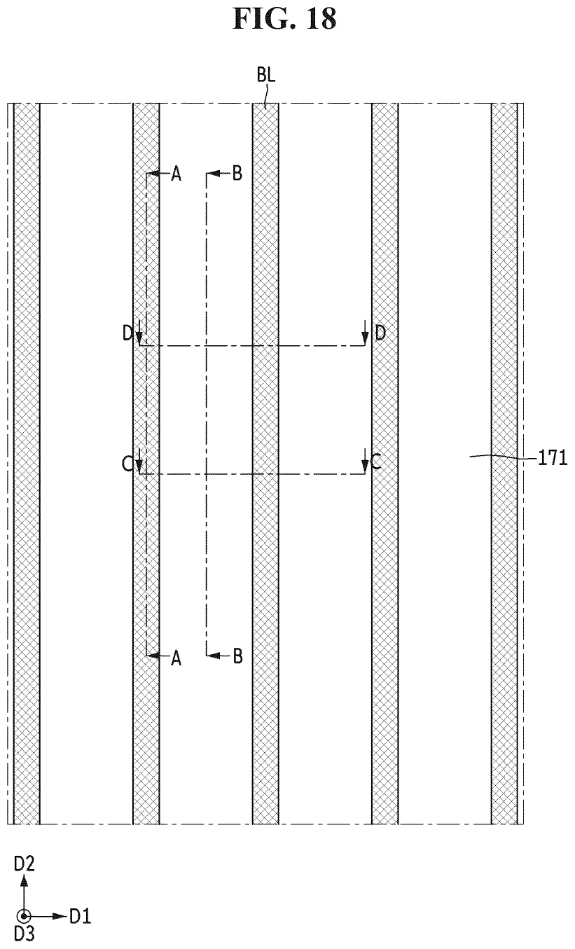

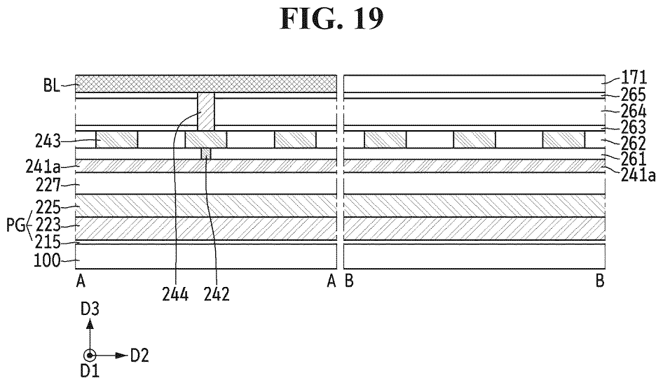

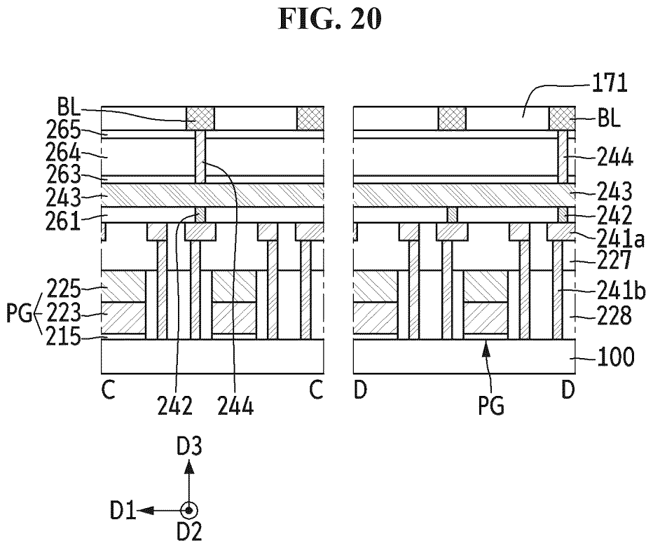

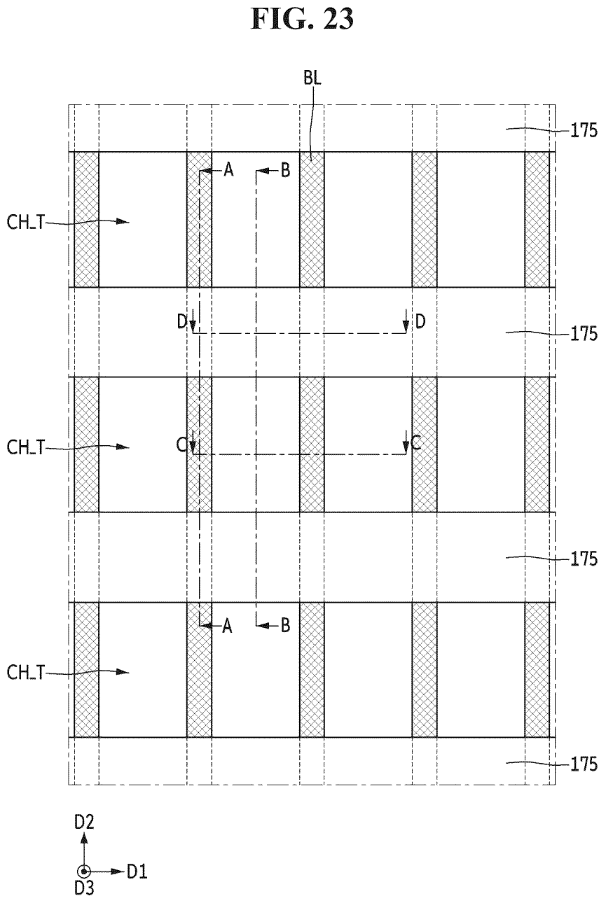

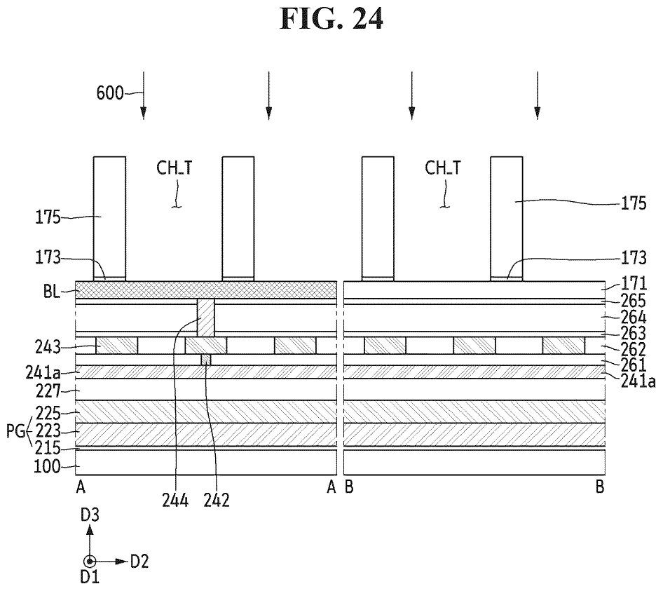

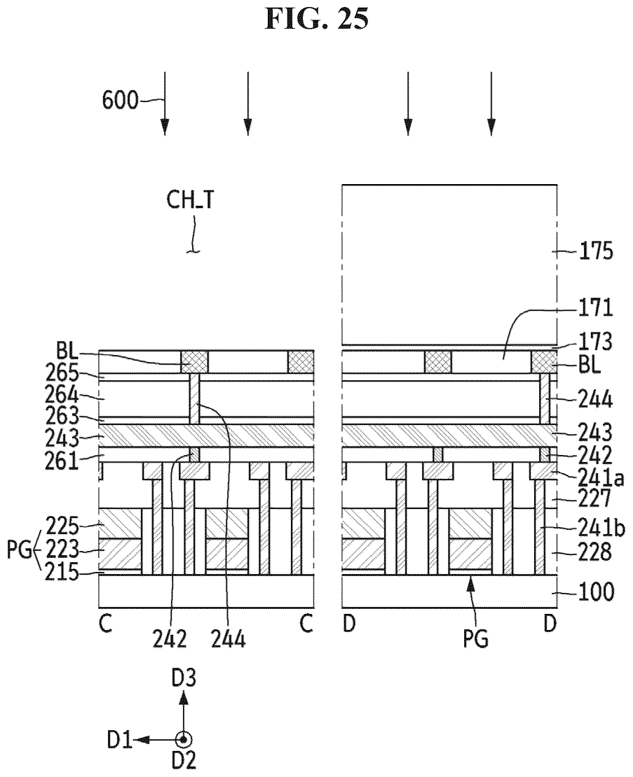

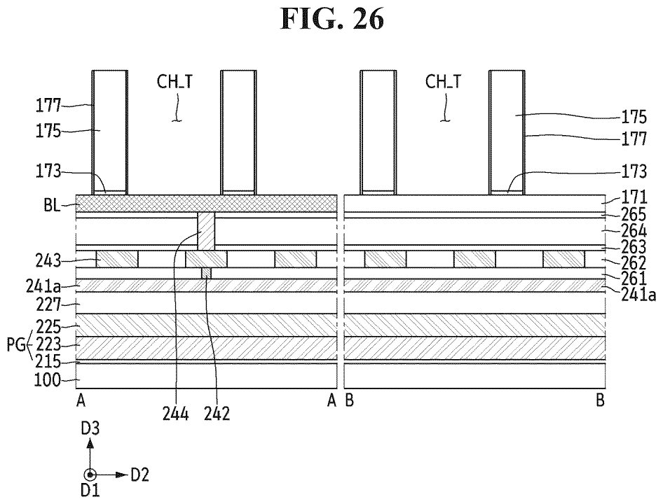

FIGS. 18 to 34 are diagrams for illustrating a semiconductor memory device according to some embodiments of the present disclosure. For convenience of description, contents duplicate with what has been described above in FIGS. 1 to 4 may be briefly described or repeated descriptions thereof may be omitted.

Referring to FIGS. 18 to 20, the peripheral gate structure PG may be formed on the substrate 100.

The first peripheral wiring line 241a and the peripheral contact plug 241b may be formed on the substrate 100.

The first through fourth peripheral upper insulating films 261, 262, 263, 264, and 265 may be sequentially formed on the first peripheral wiring line 241a and the peripheral contact plug 241b. The second peripheral wiring line 243, the peripheral via plug 242, and the cell connection plug 244 may be formed within the first through fourth peripheral upper insulating films 261, 262, 263, 264, and 265.

Subsequently, the bit-line BLs may be formed on the fifth peripheral upper insulating film 265. The bit-line BL may extend long in the second direction D2 while being disposed on the substrate 100. The cell lower insulating film 171 may be formed on the fifth peripheral upper insulating film 265. The cell lower insulating film 171 may not cover the upper surface of the bit-line BL so as to be exposed.

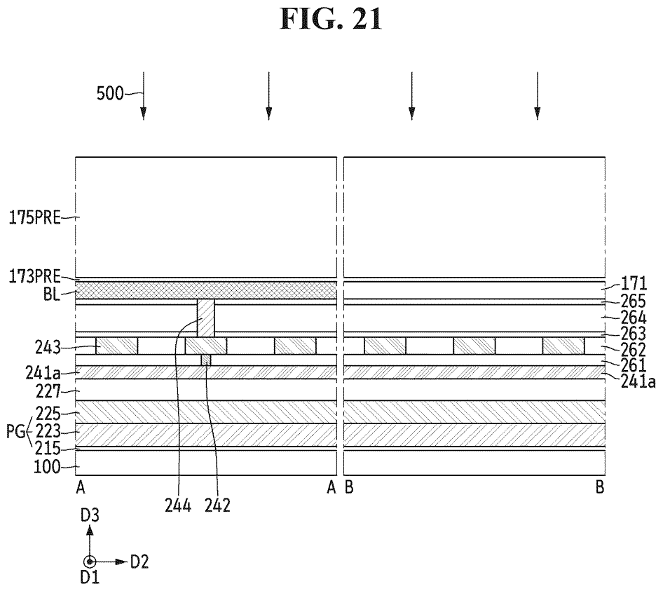

Referring to FIGS. 21 to 26, a pre-cell lower etch stop film 173PRE and a pre-protruding insulating pattern 175PRE may be formed on the bit-line BL.

Subsequently, an etching process 500 may be performed to form the cell lower etch stop film 173 and the protruding insulating pattern 175. The protruding insulating pattern 175 may include a plurality of channel trenches CH_T extending in the first direction D1. The channel trench CH_T may intersect the bit-line BL. The channel trench CH_T may expose the bit-line BL. According to embodiments, a native oxide film may be formed on the exposed bit-line BL.

Subsequently, a fluorine surface treatment 600 may be performed. The fluorine surface treatment 600 may include fluorine plasma, a clean process including fluorine (e.g., an HF clean process), chemical vapor deposition (CVD), or physical vapor deposition (PVD). The native oxide film formed on the bit-line BL may be removed by the fluorine surface treatment 600. In addition, the liner film 177 may be formed on the sidewall of the protruding insulating pattern 175 and the sidewall of the cell lower etch stop film 173 in the fluorine surface treatment 600. The liner film 177 may contain fluorine.

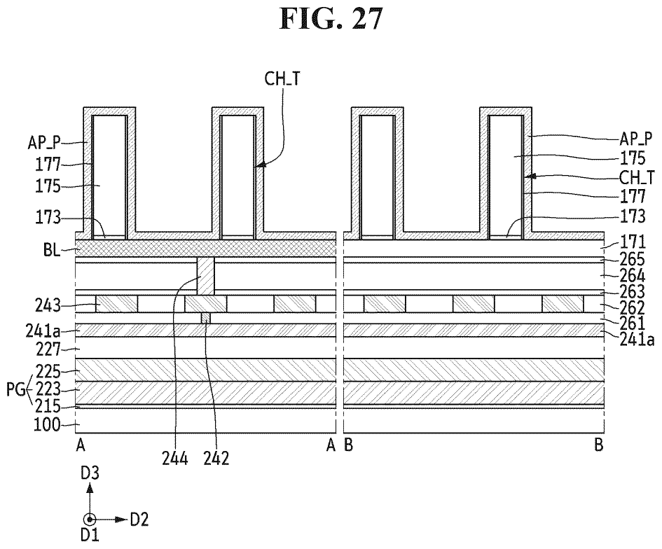

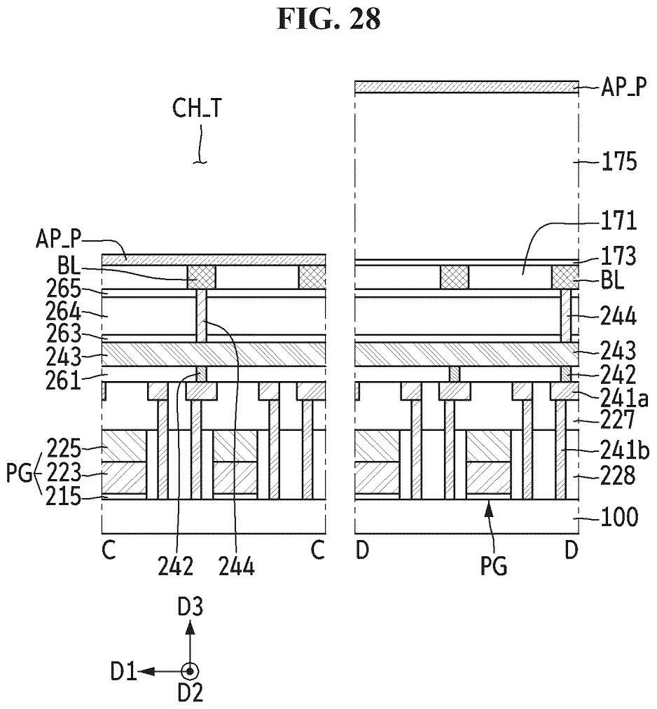

Referring to FIG. 27 and FIG. 28, a pre-channel structure AP_P may be formed along a sidewall and a bottom surface of the channel trench CH_T.

The pre-channel structure AP_P may be formed on the bit-line BL. The pre-channel structure AP_P may be formed along the sidewall and the upper surface of the protruding insulating pattern 175.

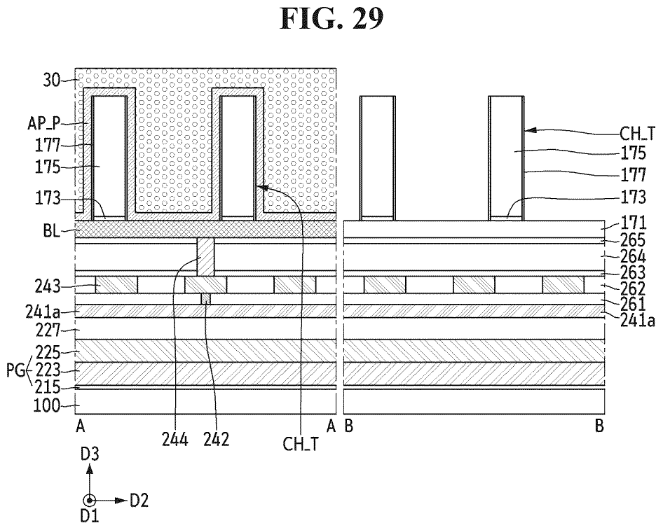

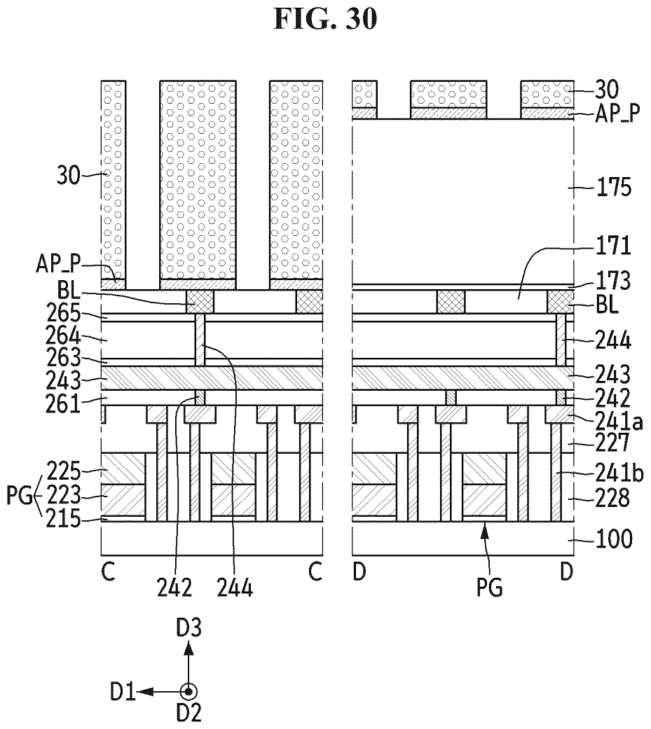

Referring to FIG. 29 and FIG. 30, a sacrificial film 30 may be formed on the pre-channel structure AP_P.

The sacrificial film 30 may be formed on the pre-channel structure AP_P. The sacrificial film 30 may fill the channel trench CH_T. The sacrificial film 30 may be made of an insulating material or a silicon oxide and may be formed using spin on glass (SOG). However, embodiments of the present disclosure are not limited thereto.

Subsequently, a mask pattern may be formed on the sacrificial film 30 and the pre-channel structure AP_P. Using the mask pattern as an etch mask, the sacrificial film 30 and the pre-channel structure AP_P may be etched. A portion of the pre-channel structure AP_P and a portion of the sacrificial film 30 on the cell lower insulating film 171 may be removed. As a result, the sacrificial film 30 and the pre-channel structure AP_P may be spaced apart from each other in the first direction D1.

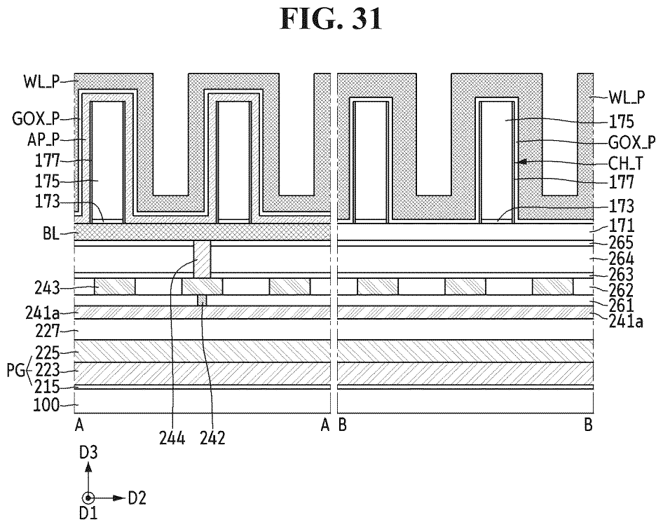

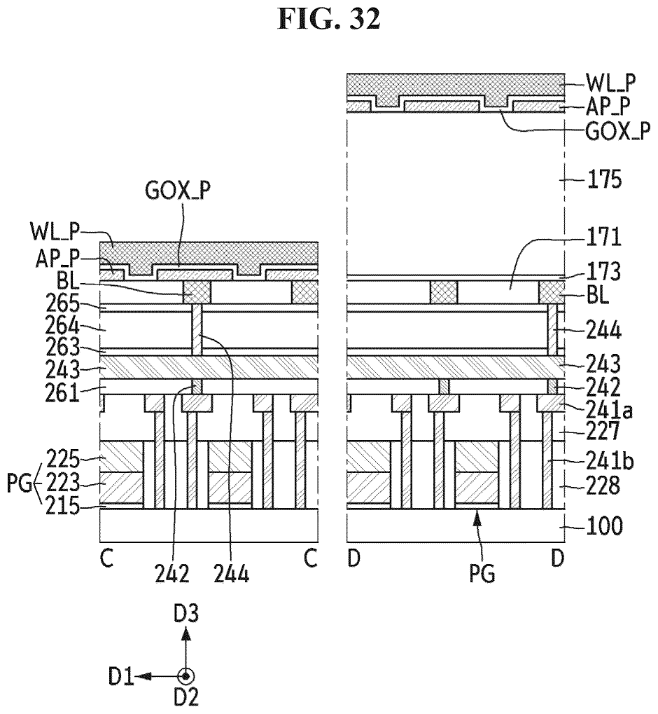

Referring to FIG. 31 and FIG. 32, the sacrificial film 30 may be removed, and a pre-gate insulating film GOX_P and a pre-word-line WL_P may be formed.

Specifically, the sacrificial film 30 may be removed, and the pre-channel structure AP_P, a portion of the cell lower insulating film 171, and the protruding insulating pattern 175 may be exposed. Subsequently, the pre-gate insulating film GOX_P and the pre-word-line WL_P may be formed sequentially on the pre-channel structure AP_P, the cell lower insulating film 171, and the protruding insulating pattern 175.

The pre-gate insulating film GOX_P may be formed using at least one from among physical vapor deposition (PVD), thermal chemical vapor deposition (thermal CVD), low pressure chemical vapor deposition (LP-CVD), plasma enhanced chemical vapor deposition (PECVD), and atomic layer deposition (ALD). However, embodiments of the present disclosure are not limited thereto.

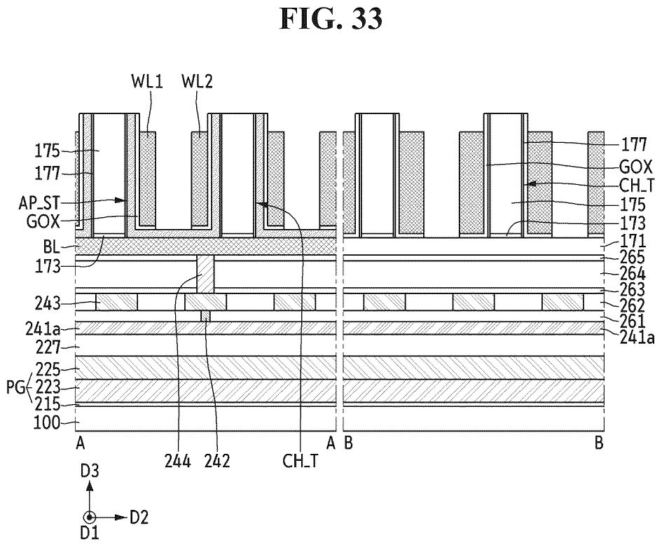

Referring to FIG. 33, the channel structure AP_ST, the first word-line WL1, and the second word-line WL2 may be formed.

Specifically, an anisotropic etching process may be performed on the pre-word-line WL_P. During the anisotropic etching process on the pre-word-line WL_P, a portion of the pre-word-line WL_P on the upper surface of the protruding insulating pattern 175 may be removed, such that the first word-line WL1 and the second word-line WL2 may be formed. In addition, a portion of the pre-gate insulating film GOX_P and a portion of the pre-channel structure AP_P on the upper surface of the protruding insulating pattern 175 may be removed, so that the gate insulating film GOX and the channel structure AP_ST may be formed, respectively.

In some embodiments, during the anisotropic etching process on the pre-word-line WL_P, a portion of the gate insulating film GOX may be etched. Thus, a portion of the gate insulating film GOX between the first word-line WL1 and the channel structure AP_ST may be isolated from a portion of the gate insulating film GOX between the second word-line WL2 and the channel structure AP_ST.

In some embodiments, during the anisotropic etching process on the pre-word-line WL_P, a portion of the channel structure AP_ST between the first word-line WL1 and the second word-line WL2 may be etched. Thus, the channel structure AP_ST may be divided into the first channel pattern AP1 and the second channel pattern AP2 in FIG. 15.

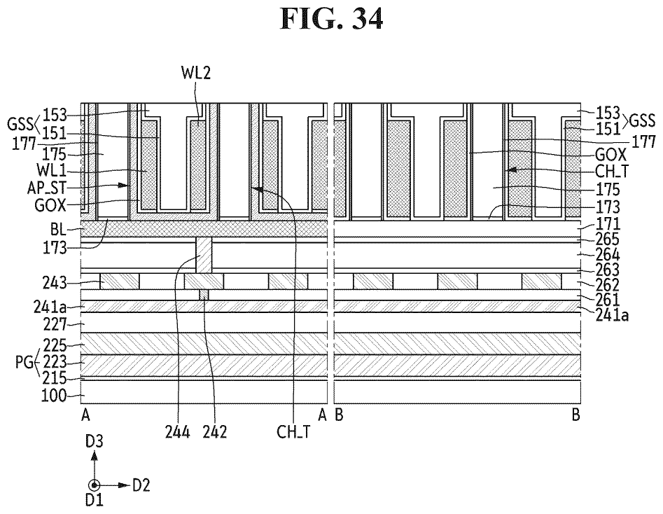

Referring to FIG. 34, the gate isolation pattern GSS may be formed on the first word-line WL1 and the second word-line WL2. The gate isolation pattern GSS may fill the channel trench CH_T.

More specifically, the gate isolation liner 151 may be formed according to a profile of the first word-line WL1 and a profile of the second word-line WL2. The gate isolation liner 151 may further be formed on the upper surface of the protruding insulating pattern 175.

A pre-filling film may be formed on the gate isolation liner 151. The pre-filling film may further be formed on the upper surface of the protruding insulating pattern 175. A portion of the pre-filling film may be removed, such that the gate isolation filling film 153 may be formed on the gate isolation liner 151.

Referring to FIG. 2 and FIG. 3, a portion of the channel structure AP_ST may be removed, such that a vertical level of the uppermost surface of the channel structure AP_ST may be lower than a vertical level of the upper surface of the protruding insulating pattern 175. Subsequently, a pre-landing pad film may be formed on the protruding insulating pattern 175, the gate isolation pattern GSS, and the channel structure AP_ST. The pre-landing pad film may be patterned such that landing pads LP may be formed on the channel structure AP_ST.

Subsequently, the data storage pattern DSP may be formed on the landing pad LP. The data storage pattern DSP may be connected to the channel structure AP_ST and may be formed on the gate isolation pattern GSS.

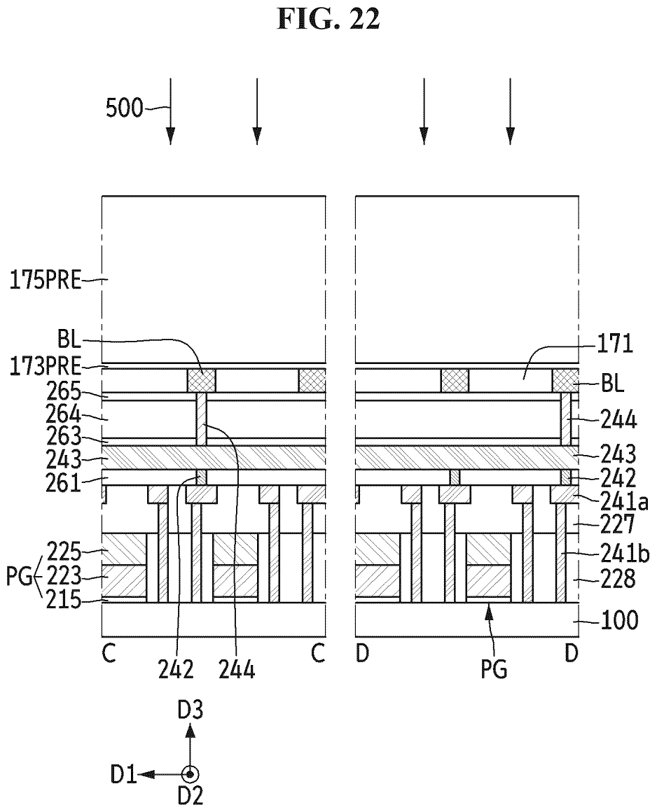

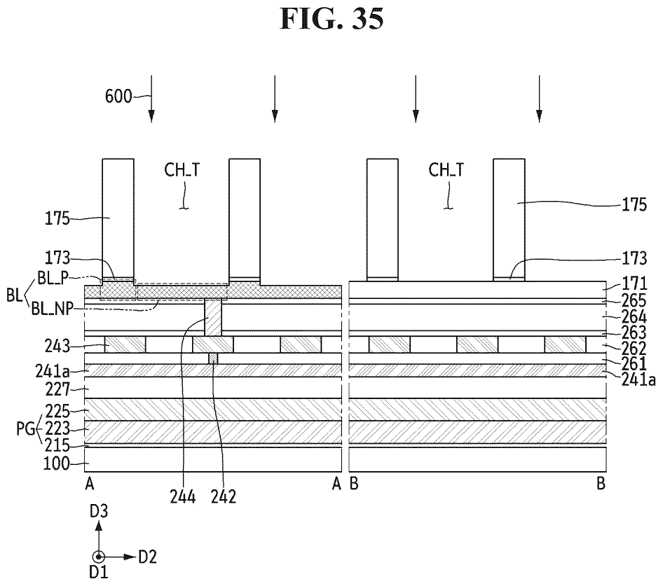

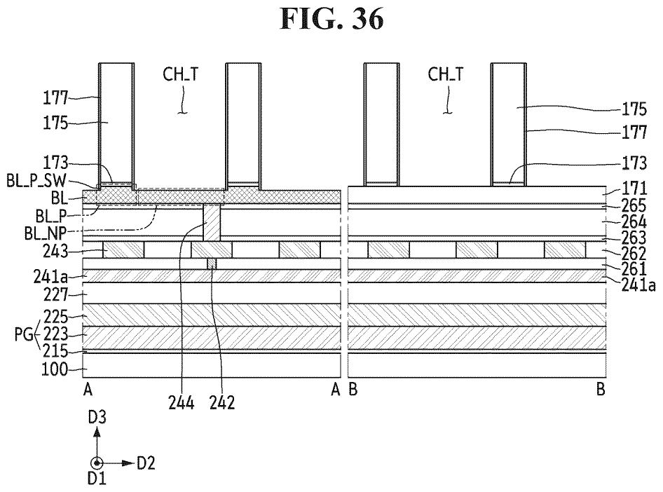

FIG. 35 and FIG. 36 are diagrams of intermediate structures corresponding to intermediate steps of a semiconductor memory device manufacturing method according to some embodiments of the present disclosure. FIG. 35 and FIG. 36 are diagrams showing a subsequent process to FIG. 21 and FIG. 22. For convenience of description, contents duplicate with those as described above with reference to FIGS. 18 to 34 may be briefly described or repeated descriptions thereof may be omitted.

Referring to FIG. 35 and FIG. 36, the cell lower etch stop film 173 and the protruding insulating pattern 175 may be formed in the etching process 500 (see FIG. 21). In the etching process 500, the protruding portion BL_P and the non-protruding portion BL_NP of the bit-line BL may be formed. The protruding portion BL_P may overlap with the protruding insulating pattern 175 in the third direction D3. The non-protruding portion BL_NP may be exposed through the channel trench CH_T.

Subsequently, the fluorine surface treatment 600 may be performed. The liner film 177 may be formed in the fluorine surface treatment 600. The liner film 177 may be formed from the portion of the sidewall BL_P_SW of the protruding portion BL_P of the bit-line BL to a side surface of the protruding insulating pattern 175.

A description of a subsequent process may be substantially the same as the description as set forth above with reference to FIGS. 27 to 34.

Although non-limiting example embodiments of the present disclosure have been described with reference to the accompanying drawings, embodiments of the present disclosure are not limited to the above example embodiments, and may be implemented in various different forms. A person skilled in the art may appreciate that embodiments of the present disclosure may be practiced in other concrete forms without departing from the technical spirit and scope of the present disclosure. Therefore, it should be appreciated that the example embodiments as described above are not restrictive and are illustrative in all respects.

What is claimed is:

1. A semiconductor memory device comprising:
a substrate;
a bit-line on the substrate and extending in a first direction;
a protruding insulating pattern on the bit-line and including a channel trench, wherein the channel trench exposes the bit-line and extends in a second direction intersecting the first direction;
a channel structure extending along a portion of a sidewall of the channel trench and a lower surface of the channel trench, wherein the channel structure comprises a first channel pattern and a second channel pattern spaced apart from the first channel pattern in the first direction;
a first word-line between the first channel pattern and the second channel pattern and extending in the second direction;
a second word-line between the first channel pattern and the second channel pattern and extending in the second direction, wherein the second word-line is spaced apart from the first word-line in the first direction;
a liner film between the protruding insulating pattern and the first channel pattern, and between the protruding insulating pattern and the second channel pattern, wherein the liner film extends along at least a portion of a sidewall of the protruding insulating pattern, and comprises fluorine; and
a first capacitor and a second capacitor between the first channel pattern and the second channel pattern, and respectively connected to the first channel pattern and the second channel pattern.

2. The semiconductor memory device of claim 1, wherein an upper surface of the liner film and an upper surface of the first channel pattern are coplanar with each other.

3. The semiconductor memory device of claim 1, wherein a vertical level of an upper surface of the liner film is higher than a vertical level of an upper surface of the first channel pattern.

4. The semiconductor memory device of claim 1, wherein the bit-line comprises:
a protruding portion overlapping with the protruding insulating pattern in a vertical direction; and
a non-protruding portion that does not overlap with the protruding insulating pattern in the vertical direction, wherein the channel structure is on the non-protruding portion,
wherein a portion of the protruding portion overlaps with the channel structure in a horizontal direction, and
wherein the liner film is on a portion of a sidewall of the protruding portion.

5. The semiconductor memory device of claim 4, wherein the liner film extends from the portion of the sidewall of the protruding portion to the sidewall of the protruding insulating pattern.

6. The semiconductor memory device of claim 4, wherein an upper surface of the protruding insulating pattern and an upper surface of the liner film are coplanar with each other.

7. The semiconductor memory device of claim 6, wherein a vertical length from an upper surface of the protruding portion to the upper surface of the protruding insulating pattern is smaller than a vertical length from an upper surface of the non-protruding portion to the upper surface of the liner film.

8. The semiconductor memory device of claim 1, further comprising a gate isolation pattern on the bit-line so as to isolate the first word-line and the second word-line from each other,
wherein the first channel pattern and the second channel pattern are connected to each other via a connection channel pattern of the channel structure, and
wherein the gate isolation pattern is on the connection channel pattern and overlaps the liner film in the first direction.

9. The semiconductor memory device of claim 1, wherein the liner film covers an entirety of the sidewall of the protruding insulating pattern.

10. The semiconductor memory device of claim 1, wherein the protruding insulating pattern comprises an etch stop film, a first mold insulating film on the etch stop film, and a second mold insulating film on the first mold insulating film.

11. The semiconductor memory device of claim 1, further comprising:
a landing pad on the first channel pattern and connecting the first channel pattern and the first capacitor to each other; and
a gate insulating film between the first channel pattern and the first word-line,
wherein the landing pad contacts the gate insulating film and the liner film.

12. The semiconductor memory device of claim 11, wherein the landing pad comprises:
a protruding landing pad on the first channel pattern; and
a horizontal landing pad on the protruding insulating pattern and the gate insulating film,
wherein the protruding landing pad is between the liner film and the gate insulating film.

13. The semiconductor memory device of claim 11, wherein the landing pad comprises:
a protruding landing pad on the first channel pattern; and
a horizontal landing pad on the protruding insulating pattern and the gate insulating film,
wherein a lower surface of the protruding landing pad is in contact with both the liner film and the first channel pattern.

14. A semiconductor memory device comprising:
a substrate;
a bit-line on the substrate and extending in a first direction;
a protruding insulating pattern on the bit-line and including a channel trench, wherein the channel trench exposes the bit-line and extends in a second direction intersecting the first direction;
a channel structure extending along a portion of a sidewall of the channel trench and a lower surface of the channel trench, wherein the channel structure comprises a first channel pattern comprising a metal oxide, and a second channel pattern spaced apart from the first channel pattern in the first direction, and wherein the second channel pattern comprises the metal oxide;
a first word-line between the first channel pattern and the second channel pattern and extending in the second direction;
a second word-line between the first channel pattern and the second channel pattern and extending in the second direction, wherein the second word-line is spaced apart from the first word-line in the first direction;
a liner film between the protruding insulating pattern and the first channel pattern, and between the protruding insulating pattern and the second channel pattern, wherein the liner film extends along at least a portion of a sidewall of the protruding insulating pattern, and comprises fluorine;
a first capacitor and a second capacitor between the first channel pattern and the second channel pattern, and respectively connected to the first channel pattern and the second channel pattern; and
at least one landing pad connecting the first channel pattern and the first capacitor to each other, and connecting the second channel pattern and the second capacitor to each other.

15. The semiconductor memory device of claim 14, wherein the liner film covers an entirety of the sidewall of the protruding insulating pattern.

16. The semiconductor memory device of claim 14, wherein the bit-line comprises:
a protruding portion overlapping with the protruding insulating pattern in a vertical direction; and
a non-protruding portion that does not overlap with the protruding insulating pattern in the vertical direction, wherein the channel structure is disposed on the non-protruding portion,
wherein a vertical level of an upper surface of the protruding portion is higher than a vertical level of an upper surface of the non-protruding portion, and
wherein the liner film is on a portion of a sidewall of the protruding portion.

17. The semiconductor memory device of claim 16, wherein the liner film extends from the portion of the sidewall of the protruding portion to the sidewall of the protruding insulating pattern.

18. The semiconductor memory device of claim 14, further comprising a gate insulating film between the first channel pattern and the first word-line and between the second channel pattern and the second word-line,
wherein a portion of the at least one landing pad is between the liner film and the gate insulating film.

19. The semiconductor memory device of claim 14, wherein the protruding insulating pattern comprises an etch stop film, a first mold insulating film on the etch stop film, and a second mold insulating film on the first mold insulating film.

20. A semiconductor memory device comprising:
a substrate;
a peripheral gate structure on the substrate;
a bit-line on the peripheral gate structure and extending in a first direction;
a protruding insulating pattern on the bit-line and including a channel trench, wherein the channel trench exposes the bit-line and extends in a second direction intersecting the first direction;
a channel structure extending along a portion of a sidewall of the channel trench and a lower surface of the channel trench, wherein the channel structure comprises a first channel pattern comprising a metal oxide, and a second channel pattern spaced apart from the first channel pattern in the first direction, wherein the second channel pattern comprises the metal oxide;
a first word-line between the first channel pattern and the second channel pattern and extending in the second direction;
a second word-line between the first channel pattern and the second channel pattern, and extending in the second direction, wherein the second word-line is spaced apart from the first word-line in the first direction;
a liner film between the protruding insulating pattern and the first channel pattern, and between the protruding insulating pattern and the second channel pattern, wherein the liner film extends along at least a portion of a sidewall of the protruding insulating pattern, and comprises fluorine;
a first capacitor and a second capacitor between the first channel pattern and the second channel pattern, and respectively connected to the first channel pattern and the second channel pattern; and
at least one landing pad connecting the first channel pattern and the first capacitor to each other, and connecting the second channel pattern and the second capacitor to each other,
wherein the bit-line comprises:
a protruding portion overlapping with the protruding insulating pattern in a vertical direction; and
a non-protruding portion that does not overlap with the protruding insulating pattern in the vertical direction, wherein the channel structure is on the non-protruding portion,
wherein a vertical level of an upper surface of the protruding portion is higher than a vertical level of an upper surface of the non-protruding portion, and
wherein the liner film extends from a portion of a sidewall of the protruding portion to the sidewall of the protruding insulating pattern.
